(19) United States
(12) Patent Application Publication
(10) Pub. No.: US 2024/0094852 A1
(43) Pub. Date: Mar. 21, 2024

(54) LAMINATE, TOUCH PANEL SENSOR, ELECTRONIC APPARATUS, METHOD OF MANUFACTURING LAMINATE

(71) Applicant: FUJIFILM Corporation, Tokyo (JP)

(72) Inventors: Takashi ARIDOMI, Minamiashigara-shi (JP); Hidehiro MOCHIZUKI, Minamiashigara-shi (JP)

(73) Assignee: FUJIFILM Corporation, Tokyo (JP)

(21) Appl. No.: 18/451,526

(22) Filed: Aug. 17, 2023

(30) Foreign Application Priority Data
Aug. 30, 2022 (JP) 2022-136999

(51) Int. Cl. G06F 3/044

(52) U.S. Cl. CPC G06F 3/044

(57) ABSTRACT

Provided is a laminate where malfunction is not likely to occur for use as a touch panel sensor.

The laminate includes: a substrate; a first wiring pattern portion that is disposed on one surface side of the substrate and consists of a plurality of first metal wires; and a second wiring pattern portion that is disposed on another surface side of the substrate and consists of a plurality of second metal wires, in which both of the first metal wires and the second metal wires include metal and carbon atoms, and in a case where an average resistivity of the first metal wires is represented by a resistivity R1 and an average resistivity of the second metal wires is represented by a resistivity R2, the resistivity R1 and the resistivity R2 are the same value or a ratio of a higher resistivity among the resistivity R1 and the resistivity R2 to a lower resistivity among the resistivity R1 and the resistivity R2 is more than 1.00 and 1.40 or less.

### CROSS-REFERENCE TO RELATED APPLICATIONS

The present application claims priority under 35 U.S.C. § 119 to Japanese Patent Application No. 2022-136999, filed on Aug. 30, 2022. The above application is hereby expressly incorporated by reference, in its entirety, into the present application.

### BACKGROUND OF THE INVENTION

### 1. Field of the Invention

The present invention relates to a laminate, a touch panel sensor, an electronic apparatus, and a method of manufacturing a laminate.

### 2. Description of the Related Art

A laminate including a wiring pattern portion consisting of a plurality of metal wires has various uses and is used for, for example, a touch panel sensor. In the laminate, the wiring pattern portion consisting of a plurality of metal wires may be formed, for example, on a substrate using ink including metal particles.

JP2019-189717A discloses a silver nanoparticle ink, and discloses that a patterned coating film is formed on one surface of the substrate using the silver nanoparticle ink and the patterned coating film is calcined to form a conductive film (wiring pattern portion).

### SUMMARY OF THE INVENTION

The present inventors prepared the laminate by forming the wiring pattern portion on one surface of the substrate with reference to the technique described in JP2019-189717A and subsequently forming the wiring pattern portion on another surface of the substrate. Here, the present inventors found that, in a case where the obtained laminate is applied to a touch panel sensor, malfunction is likely to occur. For the touch panel sensor, it is required to prevent the occurrence of malfunction, and improvement is necessary.

Accordingly, an object of the present invention is to provide a laminate where malfunction is not likely to occur for use as a touch panel sensor.

In addition, another object of the present invention is to provide a method of manufacturing the laminate.

The present inventors conducted a thorough investigation to achieve the objects, thereby completing the present invention. That is, the present inventors have found that the objects are achieved by the following configuration.

[1] A laminate comprising:
a substrate;
a first wiring pattern portion that is disposed on one surface side of the substrate and consists of a plurality of first metal wires; and
a second wiring pattern portion that is disposed on another surface side of the substrate and consists of a plurality of second metal wires,
in which both of the first metal wires and the second metal wires include metal and carbon atoms, and
in a case where an average resistivity of the first metal wires is represented by a resistivity R1 and an average resistivity of the second metal wires is represented by a resistivity R2, the resistivity R1 and the resistivity R2 are the same value, or
a ratio of a higher resistivity among the resistivity R1 and the resistivity R2 to a lower resistivity among the resistivity R1 and the resistivity R2 is more than 1.00 and 1.40 or less.

[2] The laminate according to [1],
in which the resistivity R1 and the resistivity R2 are the same value, or
a ratio of a higher resistivity among the resistivity R1 and the resistivity R2 to a lower resistivity among the resistivity R1 and the resistivity R2 is more than 1.00 and 1.20 or less.

[3] The laminate according to [1] or [2],
in which the resistivity R1 and the resistivity R2 are the same value, or
a ratio of a higher resistivity among the resistivity R1 and the resistivity R2 to a lower resistivity among the resistivity R1 and the resistivity R2 is more than 1.00 and 1.10 or less.

[4] The laminate according to any one of [1] to [3],
in which the metal is silver or copper. [5] The laminate according to any one of [1] to [4],
in which the first metal wires and the second metal wires do not substantially include halogen atoms.

[6] The laminate according to any one of [1] to [5],
in which in a case where an average value of arithmetic average roughness of the first metal wires is represented by an average value A1 and an average value of arithmetic average roughness of the second metal wires is represented by an average value A2, a ratio of a higher average value among the average value A1 and the average value A2 to a lower average value among the average value A1 and the average value A2 is 1.05 or more.

[7] The laminate according to any one of [1] to [6],
in which a content of carbon atoms with respect to all atoms of the first metal wires is 2 at % or more, the content being obtained by analyzing cross sections of the first metal wires by X-ray photoelectron spectroscopy, and
a content of carbon atoms with respect to all atoms of the second metal wires is 2 at % or more, the content being obtained by analyzing cross sections of the second metal wires by X-ray photoelectron spectroscopy.

[8] The laminate according to any one of [1] to [7],
in which a content of carbon atoms with respect to all atoms of the first metal wires is 40 at % or less, the content being obtained by analyzing cross sections of the first metal wires by X-ray photoelectron spectroscopy, and
a content of carbon atoms with respect to all atoms of the second metal wires is 40 at % or less, the content being obtained by analyzing cross sections of the second metal wires by X-ray photoelectron spectroscopy.

[9] The laminate according to any one of [1] to [8],
in which the first metal wires and the second metal wires include nitrogen atoms.

[10] The laminate according to any one of [1] to [9],
in which the first metal wires and the second metal wires include oxygen atoms.

[11] The laminate according to any one of [1] to [10],
in which the substrate is transparent.

[12] A touch panel sensor comprising:
the laminate according to any one of [1] to [11].

[13] An electronic apparatus comprising:
the touch panel sensor according to [12].

[14] A method of manufacturing a laminate, comprising:
a step 1 of forming a patterned first coating film on one surface side of a substrate using ink including at least either of metal particles or an organometallic compound and performing a first heating treatment on the first coating film; and
a step 2 of forming a patterned second coating film on another surface side of the substrate using ink including at least either of metal particles or an organometallic compound and performing a second heating treatment on the first coating film on which the heating treatment is performed in the step 1 and the second coating film to form a first wiring pattern portion and a second wiring pattern portion,
in which a value represented by a product of a heating temperature and a heating time in the second heating treatment is more than a value represented by a product of a heating temperature and a heating time in the first heating treatment.

[15] A method of manufacturing a laminate, comprising:
a step 1 of forming a first coating film on one surface side of a substrate using ink including at least either of metal particles or an organometallic compound and performing a first heating treatment on the first coating film;
a step 2 of forming a second coating film on another surface side of the substrate using ink including at least either of metal particles or an organometallic compound and performing a second heating treatment on the first coating film on which the heating treatment is performed in the step 1 and the second coating film to form a first metal layer and a second metal layer; and
a step 3 of performing an etching treatment on the first metal layer and performing an etching treatment on the second metal layer to form a first wiring pattern portion and a second wiring pattern portion,
in which a value represented by a product of a heating temperature and a heating time in the second heating treatment is more than a value represented by a product of a heating temperature and a heating time in the first heating treatment.

[16] The method of manufacturing a laminate according to [15],
in which the etching treatment is a treatment of transferring a photosensitive composition layer of a transfer film including a temporary support and the photosensitive composition layer to the first metal layer and the second metal layer, exposing the photosensitive composition layer to develop the exposed photosensitive composition layer, and etching the first metal layer and the second metal layer using the obtained pattern as a mask.

[17] The method of manufacturing a laminate according to any one of to [16],
in which the heating temperature in the second heating treatment is higher than the heating temperature in the first heating treatment.

[18] The method of manufacturing a laminate according to any one of to [17],
in which the heating temperature in the second heating treatment is higher than the heating temperature in the first heating treatment by 25 degrees or higher.

According to an aspect of the present invention, it is possible to provide a laminate where malfunction is not likely to occur for use as a touch panel sensor.

In addition, according to an aspect of the present invention, a method of manufacturing a laminate can be provided.

### DESCRIPTION OF THE PREFERRED EMBODIMENTS

Hereinafter, the details of the present invention will be described.

The constituent requirements described below may be embodied based on the representative embodiments of the present invention. However, the present invention is not limited to such embodiments.

Hereinafter, the same meanings are used in the present specification.

In the present specification, numerical ranges represented by “to” include numerical values before and after “to” as lower limit values and upper limit values.

Laminate

A laminate according to an embodiment of the present invention comprises: a substrate; a first wiring pattern portion that is disposed on one surface side of the substrate and consists of a plurality of first metal wires; and a second wiring pattern portion that is disposed on another surface side of the substrate and consists of a plurality of second metal wires. Both of the first metal wires and the second metal wires include metal and carbon atoms. Here, in the laminate according to the embodiment of the present invention, in a case where an average resistivity of the first metal wires is represented by a resistivity R1 and an average resistivity of the second metal wires is represented by a resistivity R2, the resistivity R1 and the resistivity R2 are the same value, or a ratio of a higher resistivity among the resistivity R1 and the resistivity R2 to a lower resistivity among the resistivity R1 and the resistivity R2 is more than 1.00 and 1.40 or less.

The present inventors conducted a thorough investigation on the laminate prepared with reference to the technique described in JP2019-189717A and found that, in a case where the resistivity R1 and the resistivity R2 satisfy the above-described relationship, in a case where the laminate is applied to a touch panel sensor, malfunction is not likely to occur. It is considered that, in a case where the resistivity R1 and the resistivity R2 satisfy the above-described relationship, a signal is accurately read, and malfunction is not likely to occur.

Hereinafter, a configuration of the laminate according to the embodiment of the present invention will be described.

Substrate

The laminate according to the embodiment of the present invention includes a substrate.

The substrate includes: a first main surface on which a first wiring pattern portion described below is formed; and a second main surface on which a second wiring pattern portion described below is formed.

A material of the substrate is not particularly limited and can be selected depending on purposes.

Examples of the material of the substrate include resins such as polyimide, polyethylene terephthalate, polybutylene terephthalate, polytrimethylene terephthalate, polyethylene naphthalate, polybutylene naphthalate, polycarbonate, polyurethane, polyethylene, polypropylene, polyvinyl chloride, polystyrene, polyvinyl acetate, an acrylic resin, an acrylonitrile styrene resin (AS resin), an acrylonitrile-butadiene-styrene copolymer (ABS resin), triacetyl cellulose, polyamide, polyacetal, polyphenylene sulfide, polysulfone, an epoxy resin, a glass epoxy resin, a melamine resin, a phenol resin, a urea resin, an alkyd resin, a fluororesin, and polylactic acid; inorganic materials such as silicon, soda glass, and alkali-free glass; and papers such as base paper, art paper, coated paper, cast coated paper, resin coated paper, and synthetic paper. The substrate may be composed of one layer or two or more layers. In a case where the substrate is composed of two or more layers, two or more substrates made of different materials may be laminated. In particular, the material of the substrate is preferably a resin. That is, the substrate is preferably a resin substrate.

In addition, it is also preferable that the substrate is transparent. The substrate being transparent represents that a total light transmittance of the substrate is 65% or more. The total light transmittance of the substrate is preferably 80% or more and more preferably 85% or more. The total light transmittance is, for example, less than 100%.

The thickness of the substrate is not limited. The thickness of the substrate is preferably 10 to 200 μm and more preferably 20 to 120 μm.

The thickness of the substrate is measured using the following method. Using a scanning electron microscope (SEM), a cross section in a direction (that is, a thickness direction) perpendicular to a main surface of the substrate or the laminate is observed. Based on the obtained observation image, the thickness of the substrate is measured at 10 points. By averaging the measured values, the average thickness of the substrate is obtained.

First Wiring Pattern Portion

The laminate according to the embodiment of the present invention includes the first wiring pattern portion that is disposed on one surface (first main surface) of the substrate.

The first wiring pattern portion consists of a plurality of first metal wires.

The shape of the first wiring pattern portion consisting of the first metal wires is not particularly limited and can be made to be a well-known shape. For example, the shape of a typical wiring pattern used for a touch panel sensor can be adopted. More specifically, the first wiring pattern may be a detection unit of a touch panel or may be a lead wire part that is electrically connected to a detection unit of a touch panel.

The first wiring pattern portion may be disposed on the surface of the substrate directly or through another layer.

Hereinafter, the first metal wires and characteristics thereof will be described.

First Metal Wires

Each of the plurality of first metal wires forming the first wiring pattern portion includes metal and carbon atoms.

It is preferable that the metal in the first metal wires is one or more metals selected from the group consisting of titanium, vanadium, chromium, manganese, iron, cobalt, nickel, copper, zirconium, molybdenum, ruthenium, rhodium, palladium, silver, tin, tungsten, rhenium, osmium, iridium, platinum, and gold. As the metal including the first metal wires, one or more metals selected from the group consisting of copper and silver are preferable from the viewpoint of the conductivity of the first metal wires, and silver is preferable from the viewpoint of moisture-heat resistance.

The first metal wires may include two or more metals.

The first metal wires may include carbon atoms, and the form of the carbon atoms is not particularly limited. Examples of the form of the carbon atoms in the first metal wires include a part of a carbon chain represented by —CH₂— and a part of carbon atoms forming a functional group.

The carbon atoms in the first metal wires may be derived from a component described in ink including at least either of metal particles or an organometallic compound described in a method of manufacturing of a laminate described below. In particular, it is preferable that the carbon atoms in the first metal wires are derived from the organic compound. That is, it is preferable that the first metal wires include an organic compound.

The organic compound may be a resin that may be included in the ink described below including at least either of metal particles or an organometallic compound or a cured product of a polymerizable compound having an ethylenically unsaturated group that may be included in the ink including at least either of metal particles or an organometallic compound.

The resin and the cured product of the polymerizable compound include carbon atoms, and may further include atoms selected from the group consisting of nitrogen atoms and oxygen atoms described below.

The content of carbon atoms with respect to all the atoms of the first metal wires is not particularly limited and, From the viewpoint of improving adhesiveness with the substrate, the content is preferably 2 at % or more, more preferably 3 at % or more, and still more preferably 6 at % or more. It is considered that, by adjusting the content of carbon atoms to be in the above-described preferable range, affinity to the substrate (in particular, a resin substrate) is improved, and adhesiveness is improved.

In addition, from the viewpoint of further suppressing malfunction in a case where the laminate is applied to a touch panel sensor, the content of carbon atoms with respect to all the atoms of the first metal wires is preferably 40 at % or less, more preferably 30 at % or less, and still more preferably 20 at % or less.

The content of carbon atoms with respect to all the atoms of the first metal wires is a value obtained by preparing a sample where cross sections of the first metal wires are exposed and analyzing the cross sections of the first metal wires by X-ray photoelectron spectroscopy (XPS).

The sample where the cross sections of the first metal wires are exposed can be prepared using an ultramicrotome. In this case, the cut surface may be a surface perpendicular to a direction in which the first metal wires extend, or may be a surface that is formed by oblique cutting.

The analysis by XPS is performed by irradiating the center of the prepared cross section with incident X-rays.

Conditions of the preparation of the sample where the cross sections of the first metal wires are exposed and detailed conditions of the analysis by XPS are conditions shown in Examples described below.

In addition, from the viewpoint of improving moisture-heat resistance, it is preferable that the first metal wires do not substantially include halogen atoms.

Not substantially including halogen atoms represents the content of halogen atoms with respect to all the atoms of the first metal wires is less than 0.1 at %. The content of the halogen atoms refers to the total content of fluorine, chlorine, bromine, and iodine.

The content of halogen atoms with respect to all the atoms of the first metal wires is measured using the same method as that of the content of carbon atoms with respect to all the atoms of the first metal wires.

In addition, it is also preferable that the first metal wires include nitrogen atoms.

In a case where the first metal wires include nitrogen atoms, the form of the nitrogen atoms is not particularly limited as long as the first metal wires include nitrogen atoms. Examples of the form of the nitrogen atoms in the first metal wires include ammonia or a salt thereof and an aspect (for example, an amine compound or a salt thereof) where a bond to the carbon atom is formed.

The nitrogen atoms in the first metal wires may be derived from a component described in ink including at least either of metal particles or an organometallic compound described in a method of manufacturing of a laminate described below.

From the viewpoint of improving adhesiveness with the substrate, the content of nitrogen atoms with respect to all the atoms of the first metal wires is preferably 0.1 at % or more, more preferably 0.3 at % or more, and still more preferably more than 0.5 mass %. The upper limit of the content of nitrogen atoms with respect to all the atoms of the first metal wires is, for example, 10 at % or less.

The content of nitrogen atoms with respect to all the atoms of the first metal wires is measured using the same method as that of the content of carbon atoms with respect to all the atoms of the first metal wires.

In addition, it is also preferable that the first metal wires include oxygen atoms.

In a case where the first metal wires include oxygen atoms, the form of the oxygen atoms is not particularly limited as long as the first metal wires include oxygen atoms. Examples of the form of the oxygen atoms in the first metal wires include an oxide of the metal and an aspect where a bond to the carbon atom is formed (for example, a compound having a carboxylic acid group or a salt thereof, a compound having an ester bond, or an alcohol compound).

The oxygen atoms in the first metal wires may be derived from a component described in ink including at least either of metal particles or an organometallic compound described in a method of manufacturing of a laminate described below.

From the viewpoint of improving adhesiveness with the substrate, the content of oxygen atoms with respect to all the atoms of the first metal wires is preferably 0.1 at % or more, more preferably 0.2 at % or more, and still more preferably more than 0.5 mass %. The upper limit of the content of oxygen atoms with respect to all the atoms of the first metal wires is, for example, 10 at % or less.

The content of oxygen atoms with respect to all the atoms of the first metal wires is measured using the same method as that of the content of carbon atoms with respect to all the atoms of the first metal wires.

Average Resistivity (Resistivity R1)

In the laminate according to the embodiment of the present invention, the average resistivity (resistivity R1) of the first metal wires is obtained as follows.

First, four lead-out wirings for resistance measurement having a length of 2 cm are formed using a commercially available silver paste from opposite ends of a region of the first metal wire having a substantially constant thickness and a substantially constant width. Here, the distance from one end part to another end part of the region where the lead-out wiring is formed in the direction in which the first metal wires extend is represented by a length L1. Terminals are brought into contact with the four formed lead-out wirings to measure a resistance value R (unit: S2) using a four-terminal method. In the measurement using the four-terminal method, RM3543 (manufactured by Hioki E.E. Corporation) is used.

Next, in the region, a cross section of the region perpendicular to the direction in which the first metal wires extend is prepared, and the cross section is cut using an ultramicrotome to obtain a sample. A cross section of the obtained sample is observed using a scanning electron microscope (SEM) to measure a width W1 and a height H1 of the first metal wire.

A resistivity RV (unit: Ω·m) is obtained from the following Expression (1) from the resistance value R, the length L1, the width W1, and the height H1 obtained through the procedures.

RV=(R×W1×H1)/L1 (1)

The measurement is performed on the first metal wires in the first wiring pattern portion to obtain RVs, and an arithmetic mean value of the RVs is obtained as the resistivity R1 (unit: Ω·m).

In a case where the number of the first metal wires forming the first wiring pattern portion is more than 10, RVs of any 10 first metal wires are obtained to obtain an arithmetic mean value thereof as R1. In a case where the number of the first metal wires forming the first wiring pattern portion is 10 or less, RVs of all the first metal wires are obtained to obtain an arithmetic mean value thereof as the resistivity R1.

The resistivity R1 is preferably 1.0×10⁻⁴ Ω·m or less, more preferably 1.0×10⁻⁵ Ω·m or less, and still more preferably 1.0×10⁻⁶ Ω·m or less.

The lower limit of the resistivity R1 is, for example, 1.0×10⁻⁹ Ω·m.

Arithmetic Average Roughness (Average Value A1)

In the laminate according to the embodiment of the present invention, the arithmetic average roughness (average value A1) of the first metal wires is obtained as follows.

First, a cross section perpendicular to the direction in which the first metal wires extend is prepared, and the cross section is cut using an ultramicrotome to obtain a sample. A cross section of the obtained sample is observed using a scanning electron microscope (SEM) to measure an arithmetic average roughness of a surface of the cross section of the sample opposite to the substrate side.

The preparation of the sample and the observation of the cross section are repeated five times, and an arithmetic average roughness of the obtained first metal wires is obtained as the average value A1. In a case where it is difficult to obtain five samples from the laminate, the average value A1 may be calculated from an upper limit number (4 or less) of the obtained samples. In addition, in the first wiring pattern portion, in a case where each of five or more first metal wires extend in parallel, a cross section perpendicular to the direction in which the first metal wires extend may be prepared, and surface roughness values of the five first metal wires may be obtained to calculate the average value A1.

The average value A1 is preferably 1 to 100 nm, more preferably 2 to 80 nm, and still more preferably 3 to 50 nm.

In a case where the average value A1 is the upper limit or less of the preferable range, in a case where a protective film or the like is provided such that the first metal wires and the protective film are in contact with each other, the protective film that is unnecessary is not likely to peel off. In addition, in a case where the average value A1 is the lower limit or more of the preferable range, the resistivity R1 of the first metal wires is likely to be low.

The thickness of the first metal wires is preferably 0.1 to 20 μm, more preferably 0.3 to 10 μm, and still more preferably 0.5 to 5 μm. The thickness of the first metal wires is obtained as the average value of the heights H1 in the cross sections of the first metal wires measured in the measurement of the average resistivity.

The width of the first metal wires is preferably 1 to 1000 μm, more preferably 2 to 500 μm, and still more preferably 4 to 200 μm. The width of the first metal wires is obtained as the arithmetic mean value of the widths W1 in the cross sections of the first metal wires measured in the measurement of the average resistivity.

Second Wiring Pattern Portion

The laminate according to the embodiment of the present invention includes the second wiring pattern portion that is disposed on one surface (second main surface) of the substrate.

The second wiring pattern portion consists of a plurality of second metal wires.

The shape of the second wiring pattern portion consisting of the second metal wires is not particularly limited and can be made to be a well-known shape. For example, the shape of a typical wiring pattern used for a touch panel sensor can be adopted. More specifically, the second wiring pattern may be a detection unit of a touch panel or may be a lead wire part that is electrically connected to a detection unit of a touch panel.

The second wiring pattern portion may be disposed on the surface of the substrate directly or through another layer.

Hereinafter, the second metal wires and characteristics thereof will be described.

Second Metal Wires

Each of the plurality of second metal wires forming the second wiring pattern portion includes metal and carbon atoms.

Aspects of materials in the second metal wires including preferable aspects are the same as the aspects of the materials in the first metal wires, and thus the description thereof will not be repeated.

Average Resistivity (Resistivity R2)

In the laminate according to the embodiment of the present invention, the average resistivity (resistivity R2) of the second metal wires is obtained as in the resistivity R1.

The resistivity R2 is preferably 1.0×10⁻⁴ Ω·m or less, more preferably 1.0×10⁻⁵ Ω·m or less, and still more preferably 1.0×10⁻⁶ Ω·m or less.

The lower limit of the resistivity R2 is, for example, 1.0×10⁻⁹ Ω·m or more.

In the laminate according to the embodiment of the present invention, regarding the resistivity R1 obtained using the above-described method and the resistivity R2 obtained using the above-described method, the resistivity R1 and the resistivity R2 are the same value, or a ratio (hereinafter, also simply referred to as “resistivity ratio X”) of a higher resistivity among the resistivity R1 and the resistivity R2 to a lower resistivity among the resistivity R1 and the resistivity R2 is more than 1.00 and 1.40 or less.

In other words, in a case where the resistivity R1 and the resistivity R2 are the same value, the ratio of the resistivity R2 to the resistivity R1 (or the ratio of the resistivity R1 to the resistivity R2) is 1.00, and the resistivity R1 is less than the resistivity R2, the ratio of the resistivity R2 to the resistivity R1 is more than 1.00 and 1.40 or less. In a case where the resistivity R2 is less than the resistivity R1, the ratio of the resistivity R1 to the resistivity R2 is more than 1.00 and 1.40 or less.

From the viewpoint of further suppressing malfunction in a case where the laminate is applied to a touch panel sensor, it is preferable that the resistivity R1 and the resistivity R2 are the same value or the resistivity ratio X is more than 1.00 and 1.20 or less, and it is more preferable that the resistivity R1 and the resistivity R2 are the same value or the resistivity ratio X is more than 1.00 and 1.10 or less.

Arithmetic Average Roughness (Average Value A2)

In the laminate according to the embodiment of the present invention, the arithmetic average roughness (average value A2) of the second metal wires is obtained as follows.

The average value A2 is preferably 1 to 100 nm, more preferably 2 to 80 nm, and still more preferably 3 to 50 nm.

In a case where the average value A2 is the upper limit or less of the preferable range, in a case where a protective film or the like is provided such that the second metal wires and the protective film are in contact with each other, the protective film that is unnecessary is not likely to peel off. In addition, in a case where the average value A2 is the lower limit or more of the preferable range, the resistivity R2 of the second metal wires is likely to be low.

In the laminate according to the embodiment of the present invention, it is preferable that the ratio of a higher average value among the average value A1 and the average value A2 to a lower average value among the average value A1 and the average value A2 is 1.05 or more. The upper limit is not particularly limited, and is preferably 2.0 or less.

In the laminate, a protective film may be provided such that the first wiring pattern portion and the second wiring pattern portion are in contact with each other. In addition, the laminate where the protective film is formed on opposite surfaces may be handled using a roll-to-roll method. In a case where the laminate where the protective film is formed on opposite surfaces is handled using a roll-to-roll method, in a case where the ratio between the average values is 1.05 or more, only the protective film on one side (for example, the side to be processed) can be stably peeled off.

In a case where the average value A1 is more than the average value A2, the resistivity R2 is likely to be more than the resistivity R1. On the other hand, in a case where the average value A2 is more than the average value A1, the resistivity R1 is likely to be more than the resistivity R2. That is, in a case where the arithmetic average roughness of the first metal wires is high, the average resistivity of the first metal wires tends to decrease. In a case where the arithmetic average roughness of the second metal wires is high, the average resistivity of the second metal wires tends to decrease.

Preferable aspects of the thickness and the width of the second metal wires are the same as the preferable aspects of the thickness and the width of the first metal wires, and thus the description thereof will not be repeated. The thickness and the width of the second metal wires are obtained using the same measuring method as that of the first metal wires.

### Method of Manufacturing Laminate (First Embodiment)

Hereinafter, a first embodiment of a method of manufacturing the laminate according to the embodiment of the present invention will be described.

The first embodiment of the method of manufacturing the laminate according to the embodiment of the present invention comprises:
a step 1 of forming a patterned first coating film on one surface side of a substrate using ink including at least either of metal particles or an organometallic compound and performing a first heating treatment on the first coating film; and
a step 2 of forming a patterned second coating film on another surface side of the substrate using ink including at least either of metal particles or an organometallic compound and performing a second heating treatment on the first coating film on which the heating treatment is performed in the step 1 and the second coating film to form a first wiring pattern portion and a second wiring pattern portion,
in which a value represented by a product of a heating temperature and a heating time in the second heating treatment is more than a value represented by a product of a heating temperature and a heating time in the first heating treatment.

In the first embodiment of the method of manufacturing the laminate, the laminate according to the embodiment of the present invention can be manufactured.

In a case where the value represented by the product of the heating temperature and the heating time in the second heating treatment is less than the value represented by the product of the heating temperature and the heating time in the first heating treatment, the amount of heat applied during the formation of the first wiring pattern portion after the second heating treatment is much more than the amount of heat applied during the formation of the second wiring pattern. That is, the amounts of heat in both of the first heating treatment and the second heating treatment are supplied during the formation of the first wiring pattern portion. On the other hand, only the amount of heat in the second heating treatment is supplied during the formation of the second wiring pattern portion. Therefore, in a case where the value represented by the product of the heating temperature and the heating time in the second heating treatment is less than the value represented by the product of the heating temperature and the heating time in the first heating treatment, the amount of heat supplied during the formation of the first wiring pattern portion is excessively large, a difference in resistivity between the formed first wiring pattern portion and the formed second wiring pattern portion increases, and the requirement of the resistivity ratio tends not to be satisfied.

Hereinafter, each of the steps and steps that may be included will be described.

Step 1

In the step 1, a patterned first coating film is formed on one surface side of a substrate using ink including at least either of metal particles or an organometallic compound, and a first heating treatment is performed on the first coating film.

The first coating film may be disposed on the surface of the substrate directly or through another layer.

A method of forming the patterned first coating film is not particularly limited, and examples thereof include an ink jet method, a roll coating method, a blade coating method, a wire bar coating method, and a spray coating method.

The patterned first coating film may be formed by applying the ink including at least either of metal particles or an organometallic compound using the above-described method and subsequently removing a component such as a solvent in the ink. That is, a process of drying the patterned first coating film may be performed. It is preferable that the process of drying the first coating film is performed at a temperature lower than the heating temperature of the first heating treatment.

The pattern shape of the first coating film is not particularly limited, and a well-known pattern shape can be adopted. For example, the shape of a typical wiring pattern used for a touch panel sensor can be adopted.

Hereinafter, the ink including at least either of metal particles or an organometallic compound (hereinafter, also referred to as “first metal-containing ink”) and the first heating treatment will be described.

First Metal-Containing Ink

The first metal-containing ink is an ink composition including at least either of metal particles or an organometallic compound and a solvent.

The first metal-containing ink may include additives other than the metal particles, the organometallic compound, and the solvent.

In particular, it is preferable that the first metal-containing ink include metal particles.

It is preferable that the material forming the metal particles is one or more metals selected from the group consisting of titanium, vanadium, chromium, manganese, iron, cobalt, nickel, copper, zirconium, molybdenum, ruthenium, rhodium, palladium, silver, tin, tungsten, rhenium, osmium, iridium, platinum, and gold. From the viewpoint of the conductivity of the metal wire in the formed first wiring pattern, as the metal in the metal particles, one or more metals selected from the group consisting of copper and silver are preferable, and silver is more preferable from the viewpoint of moisture-heat resistance.

The metal particles may include two or more metals. The metal particles including two or more metals represents both an aspect including metal particles formed of one metal and metal particles formed of another metal and an aspect where one kind of metal particles include two or more metals.

In a case where one kind of metal particles include two or more metals, the two or more metals in the metal particles may be dissolved, may be phase-separated, or may form an intermetallic compound. In addition, in a case where one kind of metal particles include two or more metals, the metal particles may be core-shell particles.

It is preferable that the metal particles include nanoparticles. That is, it is preferable that the metal particles include nanoparticles selected from the group consisting of copper nanoparticles and silver nanoparticles, and it is more preferable that the metal particles include silver nanoparticles.

An average particle diameter of the metal particles is preferably 10 to 500 nm and more preferably 10 to 200 nm.

The average particle diameter of the metal particles is obtained, for example, using a dynamic light scattering method. Examples of an analysis apparatus in the dynamic light scattering method include “ZETA NANOSIZER SERIES NANO S (trade name; manufactured by Malvern Panalytical Ltd.).

In a case where the metal particles include silver nanoparticles, the metal particles may include submicron particles having a larger average particle diameter than the silver nanoparticles. By using the nano-sized silver nanoparticles and the submicron-sized silver submicron particles in combination, the melting point of the silver nanoparticles decreases in the vicinity of the silver submicron particles. Therefore, an excellent conductive path is likely to be obtained.

In addition, in a case where the metal particles include silver nanoparticles, from the viewpoint that migration can be suppressed, the metal particles may include particles including metal other than silver in addition to the silver nanoparticles. It is preferable that the metal other than silver is metal that emits electrons such that a standard electrode potential of stable ions in an ionization reaction is 0 V or higher with respect to a standard hydrogen electrode.

Examples of the metal having a standard electrode potential of 0 V or higher include gold, copper, platinum, palladium, rhodium, iridium, osmium, ruthenium, and rhenium. Among these, gold, copper, platinum, or palladium is preferable.

The metal particles can be obtained using a well-known method, and the method is not particularly limited.

Surfaces of the metal particles may be modified to prevent aggregation. Examples of a material that modifies the surfaces of the metal particles include an organic compound having a group that interacts with the surfaces of the metal particles. Examples of the organic compound having a group that interacts with the surfaces of the metal particles include a surfactant and a resin having an interactive group.

Examples of the surfactant include a compound that has an amino group, a group having a quaternary ammonium structure, a carboxy group, a hydroxy group, a thiol group, or the like as a hydrophilic group and has an alkyl group as a hydrophobic group. The surfactant may be a compound having two or more hydrophilic groups.

Examples of the resin having an interactive group include a resin that has an amino group, a group having a quaternary ammonium structure, a carboxy group, a hydroxy group, or a carbonyl group in the structure.

The surfaces of the metal particles may be modified when the metal particles are obtained (for example, during chemical synthesis) or after the metal particles are obtained.

A part of the metal particles may be oxidized or may be formed of an oxide. The oxide in the metal particles is preferably 30 mass % or less, more preferably 20 mass % or less, and still more preferably 10 mass % or less with respect to the total mass of the metal particles.

The content of the metal particles in the first metal-containing ink is preferably 1 to 50 mass %, more preferably 5 to 40 mass %, and still more preferably 20 to 40 mass % with respect to the total mass of the first metal-containing ink.

The content of the metal particles in the first metal-containing ink is preferably 40 to 99.9 mass %, more preferably 60 to 99 mass %, and still more preferably 70 to 99 mass % with respect to the total solid content in the first metal-containing ink.

The solid content refers to components in the first metal-containing ink other than the solvent. Even in a case where the properties of the components are liquid, they are calculated as solid contents.

The organometallic compound refers to a compound having a metal-carbon bond a metal salt where metal ions and organic compound ions are electrostatically bonded to each other, or a compound such as a metal complex including metal atoms and an organic compound.

Examples of the metal atoms in the organometallic compound include the metal in the metal particles, and preferable examples of the metal are also the same.

Examples of the organic compound in the organometallic compound include an amine compound, a carboxylic acid compound, and an amide compound. The organometallic compound may include an inorganic matter other than the metal atoms and the organic compound. Examples of the inorganic matter include a halogen atom and an ammonium ion.

The organometallic compound is preferably a metal salt. The metal salt is preferably a metal carboxylate.

The first metal-containing ink may include two or more organometallic compounds.

In addition, as the ink including the organometallic compound, ink described in paragraphs “0077” to “0144” of WO2022/091883A may be used.

The solvent is not particularly limited as long as it can disperse the metal particles or it can dissolve or disperse the organometallic compound, and a well-known solvent can be used.

A boiling point of the solvent is preferably 30° C. to 300° C. and more preferably 50° C. to 200° C.

Examples of the solvent include a hydrocarbon solvent, a carbamate solvent, an amide solvent, an ether solvent, an ester solvent, an alcohol solvent, and water.

The solvents may be used alone or in combination of two or more kinds.

Examples of the hydrocarbon solvent include a linear, branched, or cyclic hydrocarbon solvent having 6 to 20 carbon atoms. Examples of the hydrocarbon include pentane, hexane, heptane, octane, nonane, decane, cyclohexane, benzene, toluene, and xylene.

The ether solvent may be any of a linear ether, a branched ether, and a cyclic ether. Examples of the ether solvent include diethyl ether, dipropyl ether, dibutyl ether, methyl-t-butyl ether, tetrahydrofuran, tetrahydropyrane, dihydropyrane, and 1,4-dioxane.

The alcohol solvent may be any of a primary alcohol, a secondary alcohol, and a tertiary alcohol and may be a polyhydric alcohol having a plurality of hydroxy groups. Examples of the alcohol solvent include ethanol, ethylene glycol, polyethylene glycol, 1-propanol, 2-propanol, propylene glycol, polypropylene glycol, 1-methoxy-2-propanol, 1-butanol, 2-butanol, butylene glycol, 1-pentanol, 2-pentanol, 3-pentanol, 1-hexanol, 2-hexanol, 3-hexanol, hexylene glycol, cyclohexanol, 3,3,5-trimethylcyclohexanol, 1-octanol, 2-octanol, 3-octanol, tetrahydrofurfuryl alcohol, cyclopentanol, terpineol, and decanol.

Examples of the ketone solvent include acetone, methyl ethyl ketone, methyl isobutyl ketone, and cyclohexanone.

Examples of the ester solvent include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

Examples of the additives that may be included in the first metal-containing ink include a resin.

In a case where the first metal-containing ink includes a resin, adhesiveness with the substrate is likely to be improved. Examples of the resin include a thermoplastic resin such as a polyester resin, a (meth)acrylic resin, a polyethylene resin, a polystyrene resin, or a polyamide resin. In addition, the resin may be a thermosetting resin such as an epoxy resin, an amino resin, or a polyimide resin.

Examples of the additives include a polymerizable compound having an ethylenically unsaturated group (ethylenically unsaturated polymerizable compound). The ethylenically unsaturated polymerizable compound is preferably a compound (polyfunctional ethylenically unsaturated compound) having 2 or more ethylenically unsaturated groups in a molecule. As the ethylenically unsaturated polymerizable compound, for example, a (meth)acrylate compound, a vinylbenzene compound, or a bismaleimide compound is preferable, and a polyvalent (meth)acrylate compound is more preferable. Examples of the polyvalent (meth)acrylate compound include an ester compound of a polyhydric alcohol and acrylic acid or methacrylic acid. In addition, the polyvalent (meth)acrylate compound may be, for example, an oligomer having several (meth)acryloyloxy groups in a molecule and a molecular weight of several hundreds to several thousands, the oligomer being called urethane (meth)acrylate, polyester (meth)acrylate, or epoxy (meth)acrylate.

In a case where the first metal-containing ink includes the polymerizable compound having an ethylenically unsaturated group as the additive, it is preferable that the first metal-containing ink further includes a polymerization initiator. Examples of the polymerization initiator include a photopolymerization initiator and a thermal polymerization initiator, and a thermal polymerization initiator is preferable.

Examples of other additives that may be included in the first metal-containing ink include a dispersant, a reducing agent, a rust inhibitor, a thickener, and a surfactant.

First Heating Treatment

In the step 1, the first heating treatment is performed on the first coating film that is formed using the first metal-containing ink.

A method of performing the first heating treatment is not particularly limited, and examples thereof include heating with an oven.

Here, a heating temperature in the first heating treatment will be referred to as a temperature S1 (unit: ° C.), and a heating time in the first heating treatment will be referred to as a time T1 (unit: min). The temperature S1 is a temperature of an atmosphere where the first heating treatment is performed.

The temperature S1 can be appropriately set depending on the components in the first metal-containing ink. For example, in a case where the first metal-containing ink includes silver nanoparticles as the metal particles, the temperature S1 is preferably 80° C. to 180° C., more preferably 90° C. to 160° C., still more preferably 90° C. to 130° C., and still more preferably 90° C. to 120° C.

In addition, in a case where the first metal-containing ink including the metal particles is used in the step 1, a temperature of the necking of the metal particles in the first metal-containing ink starts will be referred to as a temperature Snt1 (unit: ° C.). Here, a value obtained by subtracting the temperature S1 from the temperature Snt1 is preferably −40° C. to 60° C., more preferably −20° C. to 50° C., still more preferably 0° C. to 50° C., and still more preferably 10° C. to 50° C.

The temperature where the necking of the metal particles starts is measured as follows. First, the first metal-containing ink including the metal particles is applied to a glass substrate with a given width and is dried at room temperature (25° C.) to form a coating film. A surface resistivity of the coating film is measured using LORESTA GP (manufactured by Mitsubishi Chemical Analytech Co., Ltd.). First, the coating film is heated using an oven set to 50° C. for 10 minutes, and an electrical resistivity after the heating is measured. While increasing the set temperature of the oven at a temperature increase rate of 5° C., the heating and the measurement are repeated until the set temperature of the oven reaches 200° C. Here, a temperature at which the electrical resistivity after heating is 90% or more with respect to the electrical resistivity after initial heating at 200° C. is the temperature at which the necking of the metal particles starts.

The time T1 can be appropriately set depending on the components in the first metal-containing ink and the temperature S1. For example, in a case where the first metal-containing ink including silver nanoparticles as the metal particles is used, the time T1 is preferably 0.5 to 120 minutes, more preferably 2 to 60 minutes, still more preferably 10 to 45 minutes, and still more preferably 20 to 45 minutes.

Step 2

In the step 2, a patterned second coating film is formed on another surface side of the substrate using ink including at least either of metal particles or an organometallic compound (hereinafter, also referred to as “second metal-containing ink”), and a second heating treatment is performed on the first coating film on which the heating treatment is performed in the step 1 and the second coating film to form a first wiring pattern portion and a second wiring pattern portion.

The second coating film may be disposed on the surface of the substrate directly or through another layer.

A method of forming the patterned second coating film is not particularly limited, and the same method as the method of forming the first coating film can be adopted.

The patterned second coating film may be formed by applying the second metal-containing ink using the above-described method and subsequently removing a component such as a solvent in the ink. That is, a process of drying the patterned second coating film may be performed. It is preferable that the process of drying the second coating film is performed at a temperature lower than the heating temperature of the second heating treatment.

The pattern shape of the second coating film is not particularly limited, and a well-known pattern shape can be adopted. For example, the shape of a typical wiring pattern used for a touch panel sensor can be adopted.

Hereinafter, the second metal-containing ink and the second heating treatment will be described.

Second Metal-Containing Ink

The second metal-containing ink is an ink composition including at least either of metal particles or an organometallic compound and a solvent.

As the second metal-containing ink used in the step 2, the same ink as the first metal-containing ink used in the step 1 can be used. Both of the inks may be the same as or different from each other and are preferably the same as each other.

Second Heating Treatment

In the step 2, a second heating treatment is performed on the first coating film on which the heating treatment is performed in the step 1 and the second coating film. By performing the second heating treatment, the first wiring pattern portion and the second wiring pattern portion are formed.

A method of performing the second heating treatment is not particularly limited, and examples thereof include heating with an oven.

Here, a heating temperature in the second heating treatment will be referred to as a temperature S2 (unit: ° C.), and a heating time in the second heating treatment will be referred to as a time T2 (unit: min). The temperature S2 is a temperature of an atmosphere where the second heating treatment is performed.

In this case, in the first embodiment of the method of manufacturing the laminate according to the embodiment of the present invention, a value represented by the product of the temperature S2 and the time T2 in the step 2 is more than a value represented by the product of the temperature S1 and the time T1 in the step 1.

By satisfying the above-described condition, the resistivity R1 and the resistivity R2 are the same value, or the resistivity ratio X can be made to be more than 1.00 and 1.40 or less.

The temperature S2 can be appropriately set depending on the components in the second metal-containing ink. For example, in a case where the second metal-containing ink includes silver nanoparticles as the metal particles, the temperature S2 is preferably 110° C. to 200° C., more preferably 120° C. to 180° C., still more preferably 130° C. to 170° C., and still more preferably 140° C. to 170° C.

From the viewpoint of further suppressing malfunction in a case where the laminate is applied to a touch panel sensor, it is preferable that the temperature S2 is higher than the temperature S1. A value obtained by subtracting the temperature S1 from the temperature S2 is preferably 10° C. to 80° C., more preferably 20° C. to 70° C., and still more preferably 30° C. to 60° C. In the above-described preferable range, the resistivity ratio of the laminate is likely to be in the above-described preferable range, and the ratio between the average values regarding arithmetic average roughness is likely to be 1.05 or more.

In a case where the second metal-containing ink including the metal particles is used in the step 2, a temperature of the necking of the metal particles in the second metal-containing ink starts will be referred to as a temperature Snt2 (unit: ° C.). Here, a value obtained by subtracting the temperature S2 from a higher temperature among the temperature Snt1 and the temperature Snt2 is preferably −40° C. to 30° C., more preferably −20° C. to 20° C., and still more preferably −20° C. to 10° C.

The temperature Snt2 is obtained using the same method as that of the temperature Snt1.

### Method of Manufacturing Laminate (Second Embodiment)

Hereinafter, a second embodiment of a method of manufacturing the laminate according to the embodiment of the present invention will be described.

The second embodiment of the method of manufacturing the laminate according to the embodiment of the present invention comprises:
a step 1 of forming a first coating film on one surface side of a substrate using ink including at least either of metal particles or an organometallic compound and performing a first heating treatment on the first coating film;
a step 2 of forming a second coating film on another surface side of the substrate using ink including at least either of metal particles or an organometallic compound and performing a second heating treatment on the first coating film on which the heating treatment is performed in the step 1 and the second coating film to form a first metal layer and a second metal layer; and
a step 3 of performing an etching treatment on the first metal layer and performing an etching treatment on the second metal layer to form a first wiring pattern portion and a second wiring pattern portion,
in which a value represented by a product of a heating temperature and a heating time in the second heating treatment is more than a value represented by a product of a heating temperature and a heating time in the first heating treatment.

In the second embodiment of the method of manufacturing the laminate, the laminate according to the embodiment of the present invention can be manufactured.

The second embodiment is different from the first embodiment in that the first coating film and the second coating film are not patterned and the step 3 is further provided. Since the other points are the same as those of the first embodiment, differences of the second embodiment will be mainly described.

Step 1

A first coating film is formed on one surface side of a substrate using ink including at least either of metal particles or an organometallic compound, and a first heating treatment is performed on the first coating film.

The first coating film may be provided on substantially the entire surface of one surface side of the substrate or may be provided on a part of one surface side of the substrate.

The first coating film may be disposed on the surface of the substrate directly or through another layer.

Since the method of applying the first coating film and the first heating treatment are the same as those of the first embodiment, the description thereof will not be repeated. The process of drying the first coating film may be performed.

In addition, since the ink including at least either of metal particles or an organometallic compound is the same as the first metal-containing ink described in the first embodiment, the description thereof will not be repeated.

From the viewpoint of easily improving adhesiveness between a photosensitive composition layer that can be used in the step 3 and the first metal layer formed in the step 2, it is also preferable that the ink including at least either of metal particles or an organometallic compound includes the resin or the polymerizable compound having an ethylenically unsaturated group described above.

Step 2

In the step 2, a second coating film is formed on another surface side of the substrate using ink including at least either of metal particles or an organometallic compound, and a second heating treatment is performed on the first coating film on which the heating treatment is performed in the step 1 and the second coating film to form a first metal layer and a second metal layer.

The second coating film may be disposed on the surface of the substrate directly or through another layer.

Since the method of applying the second coating film and the second heating treatment are the same as those of the first embodiment, the description thereof will not be repeated. The process of drying the second coating film may be performed.

In addition, since the ink including at least either of metal particles or an organometallic compound is the same as the second metal-containing ink described in the first embodiment, the description thereof will not be repeated.

From the viewpoint of easily improving adhesiveness between the photosensitive composition layer that can be used in the step 3 and the second metal layer formed in the step 2, it is also preferable that the ink including at least either of metal particles or an organometallic compound includes the resin or the polymerizable compound having an ethylenically unsaturated group described above.

Step 3

In the step 3, an etching treatment is performed on the first metal layer and an etching treatment is performed on the second metal layer to form a first wiring pattern portion and a second wiring pattern portion.

The pattern shapes of the first wiring pattern and the second wiring pattern are not particularly limited, and a well-known pattern shape can be adopted. For example, the shape of a typical wiring pattern used for a touch panel sensor can be adopted.

The etching treatment and the formation of the first wiring pattern portion and the second wiring pattern portion in the step 3 can be performed using a well-known method. For example, the first wiring pattern portion and the second wiring pattern portion can be formed using a so-called subtractive method. More specifically, first, the photosensitive composition layer is provided on each of the first metal layer and the second metal layer, and pattern exposure and development are performed on the photosensitive composition layer to form a resist pattern. Next, the first metal layer and the second metal layer present in an opening portion of the resist pattern are removed by etching such that the first wiring pattern portion and the second wiring pattern portion can be formed.

In the above-described procedure, after forming the resist pattern on the first metal layer, the photosensitive composition layer may be provided on the second metal layer, and exposure and development may be performed thereon to form the resist pattern.

Hereinafter, each of the procedures will be described.

A method of forming the photosensitive composition layer is not particularly limited, and examples thereof include a method using a transfer film and a method of applying a photosensitive composition to form the photosensitive composition layer. In particular, the method using a transfer film is preferable. More specifically, a method of preparing a transfer film including a temporary support and a photosensitive composition layer and bonding the transfer film to the first metal layer and the second metal layer such that the photosensitive composition layer side of the transfer film faces the first metal layer and the second metal layer is preferable.

The transfer film refers to a film including at least a temporary support and a photosensitive composition layer. The transfer film will be described below in detail.

That is, it is preferable that, in the step 3, the etching treatment is a treatment of transferring a photosensitive composition layer of a transfer film including a temporary support and the photosensitive composition layer to the first metal layer and the second metal layer, exposing the photosensitive composition layer to develop the exposed photosensitive composition layer, and etching the first metal layer and the second metal layer using the obtained pattern as a mask.

The pattern exposure refers to exposure in a patterned manner where an exposed portion and a non-exposed portion are present. A positional relationship between the exposed portion (exposed region) and the non-exposed portion (non-exposed region) in the pattern exposure can be appropriately adjusted.

In the photosensitive composition layer on which the pattern exposure is performed, the solubility in a developer changes between the exposed portion and the non-exposed portion. For example, in a case where the photosensitive composition layer is a positive tone photosensitive composition layer, the solubility of the exposed portion of the photosensitive composition layer in the developer increases with respect to that of the non-exposed portion. On the other hand, in a case where the photosensitive composition layer is a negative tone photosensitive composition layer, the solubility of the exposed portion of the photosensitive composition layer in the developer decreases with respect to that of the non-exposed portion. Examples of a method of the exposure include a well-known method.

Specifically, a method using a photo mask can be used. For example, the pattern exposure can be performed on the photosensitive composition layer through a photo mask by disposing the photo mask between the photosensitive composition layer and an exposure light source. By performing the pattern exposure on the photosensitive composition layer, the exposed portion and the non-exposed portion in the photosensitive composition layer can be formed layer.

In the exposure step, from the viewpoint of further improving the resolution ability, it is preferable to bring the photosensitive composition layer and the photo mask into contact with each other for the exposure (hereinafter, also referred to as “contact exposure”).

In the exposure step, in addition to the contact exposure described above, a proximity exposure method, a lens-based or mirror-based projection exposure method, or a direct exposure method using an exposure laser or the like may also be used.

In a case of the lens-based projection exposure, an exposure machine having a proper numerical aperture (NA) of an appropriate lens corresponding to the required resolving power and the focal depth can be used. In a case of the direct exposure method, drawing may be performed directly on the photosensitive composition layer, or reduced projection exposure may be performed on the photosensitive composition layer through a lens. Further, the exposure may be performed in the atmosphere, in a reduced pressure atmosphere, in a vacuum, or may be performed in a state where a liquid such as water is interposed between the exposure light source and the photosensitive composition layer.

In a case where the transfer film is formed using the photosensitive composition layer, the photosensitive composition layer may be exposed after peeling the temporary support or may be exposed through the temporary support. In a case where the photosensitive composition layer is exposed by contact exposure, from the viewpoint of avoiding the influence of contamination of the photo mask and foreign matter attached to the photo mask on the exposure, it is preferable that the photosensitive composition layer is exposed through the temporary support. In a case where the photosensitive composition layer is exposed through the temporary support, it is preferable that a development step described below is performed after peeling the temporary support.

Exposure light used in the pattern exposure is not particularly limited as long as it can change the solubility of the photosensitive composition layer in the developer. A dominant wavelength of the exposure light is likely to be 10 to 450 nm, preferably 300 to 450 nm, and more preferably 350 to 450 nm. “Dominant wavelength” refers to a wavelength at which the intensity is the highest.

Examples of the exposure light source include various lasers, a light emitting diode (LED), an ultrahigh pressure mercury lamp, a high pressure mercury lamp, and a metal halide lamp.

An exposure amount is preferably 5 to 200 mJ/cm² and more preferably 10 to 200 mJ/cm². The exposure amount is determined depending on a light source illuminance and an exposure time. Furthermore, the exposure amount may be measured using a well-known actinometer.

The details of the light source, the exposure amount, and the exposure method can be found in, for example, paragraphs “0146” and “0147” of WO2018/155193A, the contents of which are incorporated herein by reference.

In the pattern exposure, the photosensitive composition layer may be exposed without using the photo mask.

In a case where the photosensitive composition layer is exposed without using the photo mask (hereinafter, also referred to as “maskless exposure”), for example, the photosensitive composition layer can be exposed using a direct drawing device.

The direct drawing device can directly draw an image by using active energy rays.

Examples of the exposure light source in the maskless exposure include a laser (for example, a semiconductor laser, a gas laser, or a solid-state laser) and a mercury short arc lamp (for example, an ultrahigh pressure mercury lamp) that can emit light having a wavelength of 350 to 410 nm.

An exposure wavelength is as described above. The exposure amount is determined based on the light source illuminance and the moving speed of the laminate. A drawing pattern can be controlled by a computer.

By developing the photosensitive composition layer on which the pattern exposure is performed, the resist pattern can be formed.

For example, in a case where the photosensitive composition layer is a positive tone photosensitive composition layer, the exposed portion of the photosensitive composition layer is removed by development using a developer. On the other hand, for example, in a case where the photosensitive composition layer is a negative tone photosensitive composition layer, the non-exposed portion of the photosensitive composition layer is removed by development using a developer.

As a developing method, for example, a well-known method can be used.

Specifically, for example, a method using a developer can be used.

Examples of the developer include developers described in JP1993-072724A (JP-H5-072724A) and paragraph “0194” of WO2015/093271A.

As the developer, an alkaline aqueous solution is preferable.

Examples of an alkaline compound (compound that is dissolved in water to be alkaline) in the alkaline aqueous solution include sodium hydroxide, potassium hydroxide, sodium carbonate, potassium carbonate, sodium bicarbonate, potassium bicarbonate, tetramethylammonium hydroxide, tetraethylammonium hydroxide, tetrapropylammonium hydroxide, tetrabutylammonium hydroxide, and choline (2-hydroxyethyltrimethyl ammonium hydroxide).

The temperature of the developer is preferably 20° C. to 40° C.

As a developing method, for example, a well-known method can be used. Examples of the developing method include puddle development, shower development, spin development, and dip development.

As the developing method, a developing method described in paragraph “0195” of WO2015/093271A is preferable.

The resist pattern obtained by development may be further exposed (for example, “post-exposure) or may be further heated (so-called “post-baking”).

The etching can be performed using a well-known method.

Specific method of the etching include a method described in paragraphs “0209” and “0210” of JP2017-120435A, a method described in paragraphs “0048” to “0054” of JP2010-152155A, wet etching such as dipping in an etchant, and dry etching such as plasma etching.

As the etchant that is used for wet etching, an acidic or alkaline etchant can be appropriately selected according to the etching target.

Examples of the acidic etchant include an acidic aqueous solution including at least acidic compound and an acidic mixed aqueous solution including an acidic compound and at least one selected from the group consisting of iron(III) chloride, ammonium fluoride, and potassium permanganate.

As the acidic compound (a compound that is dissolved in water to be acidic) in the acidic aqueous solution, at least one selected from the group consisting of hydrochloric acid, sulfuric acid, nitric acid, acetic acid, hydrofluoric acid, oxalic acid, and phosphoric acid is preferable.

Examples of the alkaline etchant include an alkaline aqueous solution including at least one alkaline compound and an alkaline mixed aqueous solution including an alkaline compound and a salt (for example, potassium permanganate).

As the alkaline compound (a compound that is dissolved in water to be alkaline) in the alkaline aqueous solution, at least one selected from the group consisting of sodium hydroxide, potassium hydroxide, ammonia, an organic amine, and an organic amine salt (for example, tetramethylammonium hydroxide) is preferable.

In the etching step, the etching treatments of the first metal layer and the second metal layer may be performed simultaneously or sequentially. From the viewpoint of further improving productivity, it is preferable that the etching treatments of the first metal layer and the second metal layer are performed simultaneously.

In a case where adhesiveness between the photosensitive composition layer and the first metal layer and adhesiveness between the photosensitive composition layer and the second metal layer are excellent, adhesiveness between the formed resist pattern and the first metal layer and adhesiveness between the formed resist pattern and the second metal layer are excellent. Therefore, the first wiring pattern portion having a line width of a desired shape and the second wiring pattern portion having a line width of a desired shape are likely to be formed.

After etching the first metal layer and the second metal layer are performed, the resist pattern may be removed. Examples of the method of removing the resist pattern include a method of removing the resist pattern through a chemical treatment, and a method of removing the resist pattern using a remover is preferable.

Examples of the method of removing the resist pattern include a method of removing the resist pattern with a well-known method such as a spraying method a shower method, or a puddle method using the remover.

Transfer Film

Hereinafter, the transfer film that can be used for forming the photosensitive composition layer in the step 3 will be described.

The transfer film includes the temporary support and the photosensitive composition layer.

The transfer film may further include layers other than the photosensitive composition layer described below.

Examples of the other layers include an interlayer described below and a thermoplastic resin layer described below.

Hereinafter, each of the members and each of the components in the transfer film will be described in detail.

Temporary Support

The transfer film includes the temporary support.

The temporary support is a member that supports the photosensitive composition layer, and is finally removed through a peeling treatment.

The temporary support may be any of a monolayer structure or a multilayer structure.

As the temporary support, a film is preferable, and a resin film is more preferable. In addition, as the temporary support, a flexible film where significant deformation, shrinkage, or elongation does not occur under pressure or under pressure and heating is also preferable, and a film where deformation such as wrinkles and scratches are not present is also preferable.

Examples of the film include a polyethylene terephthalate film (for example, a biaxially stretched polyethylene terephthalate film), a polymethyl methacrylate film, a cellulose triacetate film, a polystyrene film, a polyimide film, and a polycarbonate film. Among these, a polyethylene terephthalate film is preferable.

The thickness of the temporary support is preferably 5 to 200 μm, more preferably 5 to 150 μm, still more preferably 5 to 50 μm, and still more preferably 5 to 25 μm from the viewpoints of easy handling and general-purpose properties.

The thickness of the temporary support is calculated as an average value of measured values at any five points in cross sectional observation with a scanning electron microscope (SEM).

Photosensitive Composition Layer

The transfer film has a photosensitive composition layer.

It is preferable that the photosensitive composition layer includes a resin described below and a polymerizable compound described below. It is preferable that the photosensitive composition layer includes a resin described below, a polymerizable compound described below, and a polymerization initiator described below. In addition, in the photosensitive composition layer, it is preferable that the resin described below includes an alkali-soluble resin. That is, it is preferable that the photosensitive composition layer includes the resin including the alkali-soluble resin and the polymerizable compound.

It is preferable that the photosensitive composition layer includes 10.0 to 90.0 mass % of the resin, 5.0 to 70.0 mass % of the polymerizable compound, and 0.01 to 20.0 mass % of the polymerization initiator with respect to the total mass of the photosensitive composition layer.

Hereinafter, each of the components that may be included in the photosensitive composition layer will be described.

Resin

The photosensitive composition layer may include a resin.

As the resin, an alkali-soluble resin is preferable.

As the resin, a resin that includes a constitutional unit derived from methacrylic acid, a constitutional unit derived from methyl methacrylate, and a constitutional unit derived from styrene or a constitutional unit derived from benzyl methacrylate or a resin that includes a constitutional unit derived from methacrylic acid and a constitutional unit derived from styrene is preferable, and a resin that further includes a constitutional unit having a polymerizable group is more preferable.

The Tg of the resin is preferably 60° C. to 135° C., more preferably 70° C. to 115° C., still more preferably 75° C. to 105° C., and still more preferably 80° C. to 100° C.

The weight-average molecular weight of the resin is preferably 5,000 to 500,000, more preferably 10,000 to 100,000, still more preferably 10,000 to 60,000, and still more preferably 20,000 to 50,000.

The dispersity of the resin is preferably 1.0 to 6.0, more preferably 1.0 to 5.0, still more preferably 1.0 to 4.0, and particularly preferably 1.0 to 3.0.

The content of the resin is preferably 10.0 to 90.0 mass %, more preferably 20.0 to 80.0 mass %, still more preferably 30.0 to 70.0 mass %, and still more preferably 40.0 to 60.0 mass % with respect to the total mass of the photosensitive composition layer.

Polymerizable Compound

The photosensitive composition layer may include a polymerizable compound having a polymerizable group.

“Polymerizable compound” refers to a compound that is polymerized by action of the polymerization initiator described below and is different from the resin.

The polymerizable group in the polymerizable compound may be a group relating to the polymerization reaction, and examples thereof include: a group having an ethylenically unsaturated group, such as a vinyl group, an acryloyl group, a methacryloyl group, a styryl group, or a maleimide group; and a group having a cationically polymerizable group, such as an epoxy group or an oxetane group.

In particular, as the polymerizable group, a group having an ethylenically unsaturated group is preferable, and an acryloyl group or a methacryloyl group is more preferable.

As the polymerizable compound, from the viewpoint of further improving the photosensitivity of the photosensitive composition layer, a compound having one or more ethylenically unsaturated groups (hereinafter, also referred to as “ethylenically unsaturated compound”) is preferable, and a compound having two or more ethylenically unsaturated groups in one molecule (hereinafter, also referred to as “polyfunctional ethylenically unsaturated compound”) is more preferable.

In addition, from the viewpoint of further improving resolution ability and peelability, the number of ethylenically unsaturated groups in one molecule of the ethylenically unsaturated compound is preferably 1 to 6, more preferably 1 to 3, and still more preferably 2 to 3 and still more preferably 3.

The polymerizable compound may have an alkyleneoxy group.

The polymerizable compounds may be used alone or in combination of two or more kinds thereof.

In particular, it is preferable to use three or more polymerizable compounds, and it is more preferable to use three polymerizable compounds.

The content of the polymerizable compound is preferably 10.0 to 70.0 mass %, more preferably 15.0 to 70.0 mass %, and still more preferably 20.0 to 70.0 mass % with respect to the total mass of the photosensitive composition layer.

A mass ratio of the content of the polymerizable compound to the content of the resin (the content of the polymerizable compound/the content of the resin) is preferably 0.10 to 2.00, more preferably 0.50 to 1.50, and still more preferably 0.70 to 1.10.

Polymerization Initiator

The photosensitive composition layer may include a polymerization initiator.

Examples of the polymerization initiator include well-known polymerization initiators depending on the form of the polymerization reaction. Specifically, for example, a thermal polymerization initiator and a photopolymerization initiator can be used.

The polymerization initiator may be any of a radical polymerization initiator or a cationic polymerization initiator.

It is preferable that the photosensitive composition layer includes a photopolymerization initiator.

The photopolymerization initiator is a compound that initiates the polymerization of the polymerizable compound in response to an actinic ray such as an ultraviolet ray, a visible ray, or an X-ray. Examples of the photopolymerization initiator include well-known photopolymerization initiators.

Examples of the photopolymerization initiator include a photoradical polymerization initiator and a photocationic polymerization initiator. Among these, a photoradical polymerization initiator is more preferable.

The polymerization initiators may be used alone or in combination of two or more kinds thereof.

The content of the polymerization initiator (preferably, the photopolymerization initiator) is preferably 0.1 mass % or more and more preferably 0.5 mass % or more with respect to the total mass of the photosensitive composition layer. The upper limit is preferably 20 mass % or less, more preferably 15 mass % or less, and still more preferably 10 mass % or less with respect to the total mass of the photosensitive composition layer.

Other Additives

The photosensitive composition layer may optionally include other additives in addition to the above-described components.

Examples of the other additives include a colorant, a pigment, a radical polymerization inhibitor, a benzotriazole, a carboxybenzotriazole, a sensitizer, a surfactant, a plasticizer, a heterocyclic compound (for example, triazole), a pyridine (for example, isonicotinamide), and a purine base (for example, adenine).

In addition, examples of the other additives include metal oxide particles, a chain transfer agent, an antioxidant, a dispersant; an acid proliferation agent, a development accelerator, conductive fibers, an ultraviolet absorber, a thickener, a crosslinking agent, an organic or inorganic suspending agent, and additives described in paragraphs “0165” to “0184” of JP2014-085643A, the contents of which are incorporated herein by reference.

The other additives may be used alone or in combination of two or more kinds thereof.

Interlayer

The transfer film may include an interlayer between the temporary support and the photosensitive composition layer.

For example, in a case where the thermoplastic resin layer is not provided, it is preferable that the interlayer is disposed between the temporary support and the photosensitive composition layer, and in a case where the thermoplastic resin layer is provided, it is preferable that the interlayer is disposed between the thermoplastic resin layer and the photosensitive composition layer.

Examples of the interlayer include a water-soluble resin layer and an oxygen barrier layer having an oxygen barrier function described as a “separation layer” in JP1993-072724A (JP-H5-072724A).

Thermoplastic Resin Layer

The transfer film may include a thermoplastic resin layer.

For example, in a case where the interlayer is not provided, it is preferable that the thermoplastic resin layer is disposed between the temporary support and the photosensitive composition layer, and in a case where the interlayer is provided, it is preferable that the thermoplastic resin layer is disposed between the temporary support and the interlayer.

In a case where the transfer film includes the thermoplastic resin layer, the followability to an object to be transferred in the bonding step of bonding the transfer film and the object to be transferred is improved, and the mixing of air bubbles between the object to be transferred and the transfer film can be suppressed. As a result, adhesiveness with a layer (for example, the temporary support) adjacent to the thermoplastic resin layer is improved.

Examples of the thermoplastic resin layer include layers described in paragraphs “0189” to “0193” of JP2014-085643A, the contents of which are incorporated herein by reference.

Use of Laminate

The laminate according to the embodiment of the present invention can be suitably applied to a touch panel sensor. The touch panel in the touch panel sensor is preferably a capacitive touch panel. The touch panel in the touch panel sensor can be applied to a display device such as an organic electroluminescence (organic EL) display device or a liquid crystal display device.

The method of manufacturing the laminate according to the embodiment of the present invention can be applied to manufacturing of a touch panel sensor. In addition, the method of manufacturing the laminate according to the embodiment of the present invention can be applied to: manufacturing of a conductive film such as transparent heater, a transparent antenna, an electromagnetic wave shield material, or a light control film; manufacturing of a printed wiring board or a semiconductor package; manufacturing of a pillar and a pin for interconnects between semiconductor chips and packages; manufacturing of a metal mask; and manufacturing of a tape substrate such as a chip on film (COF) or a tape automated bonding (TAB).

### EXAMPLES

The present invention will be described in more detail based on the following examples.

Materials, used amounts, ratios, treatment details, treatment procedures, and the like shown in the following Examples can be appropriately changed within a range not departing from the scope of the present invention. Accordingly, the scope of the present invention will not be restrictively interpreted by the following Examples.

Hereinafter, the present invention will be described in detail according to Examples. Unless specified otherwise, “part(s)” and “%” represent “part(s) by mass” and “mass %”. Preparation of Ink including Metal Particles

A method of preparing ink including metal particles used in Examples and Comparative Examples will be described.

Silver Nanoparticles A

First, silver nitrate (manufactured by Wako Pure Chemical Industries, Ltd.) and oxalic acid dihydrate (manufactured by Wako Pure Chemical Industries, Ltd.) were caused to react with each other to obtain silver oxalate (molecular weight: 303.78). 20.0 g of the obtained silver oxalate (65.8 mmol) was put into a 500 mL flask, and 30.0 g of n-butanol was further put thereinto to obtain a n-butanol slurry of silver oxalate.

In a state where the slurry was kept at 30° C., an amine mixed solution including 57.8 g (790.1 mmol) of n-butylamine (molecular weight: 73.14, manufactured by Daicel Corporation), 40.0 g (395.0 mmol) of n-hexylamine (molecular weight: 101.19, manufactured by Tokyo Chemical Industry Co., Ltd.), 38.3 g (296.3 mmol) of n-octylamine (molecular weight: 129.25, trade name “FARMIN 08D”, manufactured Kao Corporation), 18.3 g (98.8 mmol) of n-dodecylamine (molecular weight: 185.35, trade name “FARMIN 20D”, manufactured Kao Corporation), and 40.4 g (395.0 mmol) of N,N-dimethyl-1,3-propanediamine (molecular weight: 102.18, manufactured by Koei Chemical Industry Co., Ltd.) was added dropwise.

After the dropwise addition, the content of the flask kept at 30° C. was stirred for 2 hours, a complex forming reaction of silver oxalate and the amine compound progressed, and a white material (silver oxalate-amine complex) was formed.

After forming the silver oxalate-amine complex, the content temperature of the flask was increased to about 105° C. (103° C. to 108° C.). In a state where the flask was kept at the increased temperature, the flask was heated for 1 hour. After the heating, the silver oxalate-amine complex was thermally decomposed to obtain a suspension where the dark blue surface-modified silver nanoparticles were dispersed.

After cooling the obtained suspension, 200 g of methanol was added to the suspension, and the solution was stirred. After the stirring, the surface-modified silver nanoparticles and the solvent component were separated from each other by centrifugal separation to remove the supernatant solvent component. 60 g of methanol was added to the separated surface-modified silver nanoparticles, and the solution was stirred. Next, the surface-modified silver nanoparticles and the solvent component were separated from each other by centrifugal separation to remove the supernatant solvent component (decantation washing). Through the above-described procedure, silver nanoparticles A in a wet state were obtained.

Silver Nanoparticles B

Silver nanoparticles B were obtained using the same method as that of the silver nanoparticles A, except that the decantation washing was further repeated twice during the synthesis of the silver nanoparticles A.

Silver Nanoparticles C

Through the following procedure, silver nanoparticles C were obtained.

Preparation of Silver Halide Emulsion

The following solution 2 and the following solution 3 were simultaneously added for 20 minutes to the following solution 1 held at pH 4.5 and 38° C. in amounts corresponding to 90% of the entire amounts while stirring the solution 1. As a result, nuclear particles having a size of 0.16 μm were formed. Next, the following solution 4 and the following solution 5 were added to the obtained solution for 8 minutes, and the remaining 10% amounts of the solution 2 and the solution 3 were further added for 2 minutes. As a result, the nuclear particles grew to a size of 0.21 μm. Further, 0.15 g of potassium iodide was added to the obtained solution, and the particles were aged for 5 minutes. Then the formation of the particles was completed.

Solution 1:

| | | |
|---|---|---|
| Water | 750 | ml |
| Gelatin | 8.6 | g |
| Sodium chloride | 3 | g |
| 1,3-Dimethylimidazolidine-2-thione | 20 | mg |
| Sodium benzenethiolsulfonate | 10 | mg |
| Citric acid | 0.7 | g |

Solution 2:

| | |
|---|---|
| Water | 300 ml |
| Silver nitrate | 150 g |

Solution 3:

| | | |
|---|---|---|
| Water | 300 | ml |
| Sodium chloride | 38 | g |
| Potassium bromide | 32 | g |
| Potassium hexachloroiridate(III) (0.005% KCl 20% aqueous | 5 | ml |
| solution) | | |
| Ammonium hexachlororhodate (0.001% NaCl 20% aqueous | 7 | ml |
| solution) | | |

Solution 4:

| | | |
|---|---|---|
| Water | 100 | ml |
| Silver nitrate | 50 | g |

Solution 5:

| | | |
|---|---|---|
| Water | 100 | ml |
| Sodium chloride | 13 | g |
| Potassium bromide | 11 | g |
| Yellow prussiate of potash | 5 | mg |

Next, the particles were cleaned with water by flocculation using an ordinary method. Specifically, the temperature of the obtained solution was decreased to 35° C., and the pH was decreased (to be in a range of pH 3.6±0.2) using sulfuric acid until silver halide precipitated. Next, about 3 L of the supernatant solution was removed from the obtained solution (first water cleaning). Next, 3 L of distilled water was added to the solution from which the supernatant solution was removed, and sulfuric acid was added until silver halide precipitated. About 3 L of the supernatant solution was removed again from the obtained solution (second water cleaning). By repeating the same operation as the second water cleaning once more (third water cleaning), the water cleaning and desalting step was completed. After the water cleaning and desalting, the emulsion was adjusted to pH 6.4 and pAg 7.5, 2.5 g of gelatin, 10 mg of sodium benzenethiolsulfonate, 3 mg of sodium benzenethiosulfinate, 15 mg of sodium thiosulfate, and 10 mg of chloroauric acid were added, and chemosensitization was performed at 55° C. to obtain the optimum sensitivity. Next, 100 mg of 1,3,3a,7-tetraazaindene as a stabilizer and 100 mg of PROXEL (trade name, manufactured by ICI Co., Ltd.) as a preservative were further added to the obtained emulsion. The finally obtained emulsion was a silver nanoparticles C having an average particle diameter of 200 nm, in which the content of silver iodide was 0.08 mol %, and the ratio of silver chlorobromide was 70 mol % of silver chloride/30 mol % of silver bromide.

Copper Nanoparticles A

Through the following procedure, copper nanoparticles A were obtained.

10.0 g of copper hydroxide (0.1 mol, manufactured by Wako Pure Chemical Industries, Ltd.), 31.5 g of nonanoic acid (0.2 mol, manufactured by Tokyo Chemical Industry Co., Ltd., boiling point: 254° C.), and 18.5 g of propylene glycol monomethyl ether (PGME) (20 ml, manufactured by Kanto Chemical Co., Inc.) were weighed and put into a 200 ml three-necked flask. This mixed solution was heated to 100° C. while stirring the mixed solution, and the temperature was maintained for 20 minutes. Next, 40.5 g of hexylamine (0.4 mol, manufactured by Tokyo Chemical Industry Co., Ltd., boiling point: 130° C.) was added, and the solution was heated and stirred at 100° C. for 10 minutes. After cooling the mixed solution to 10° C. using an ice bath, a solution in which 10.0 g of hydrazine-hydrate (0.2 mol, manufactured by Kanto Chemical Co., Inc.) was dissolved in 18.5 g of PGME (20 ml, manufactured by Kanto Chemical Co., Inc.) in an ice bath was added, and the solution was stirred for 10 minutes. Next, this reaction solution was heated to 100° C., and the temperature was maintained for 10 minutes. After cooling the solution to 30° C., 33 g of hexane (50 ml, manufactured by Kanto Chemical Co., Inc.) was added. After centrifugal separation, the supernatant solution was removed. The precipitate was washed with hexane, and copper nanoparticles A covered with nonanoic acid and hexylamine were obtained.

The average particle diameter of the obtained copper nanoparticles A was 39 nm.

In addition, an X-ray diffraction pattern of the obtained copper nanoparticles A was checked, in the copper nanoparticles A, Cu (body centered cubic structure) was mainly present and Cu₂O (cubic structure) was partially present. A ratio of a 111 reflection peak intensity of Cu₂O (cubic structure) to a 111 reflection peak intensity of Cu (body centered cubic structure) was about 3%.

Preparation Procedure of Ink Including Metal Particles

Components with amounts shown in Table 1 below were mixed and were stirred in an oil bath (100 rpm) for 2.5 hours. Next, the solution was stirred and kneaded (2 minutes×3 times) using a planetary kneader (manufactured by Kurabo Industries Ltd., MAZERUSTAR KKK2508) to obtain deep brown ink A (1) (silver concentration: 35 wt %, viscosity (25° C., shear rate: 10 (1/s)): 9.8 mPa·s).

In the obtained ink A, the average particle diameter of the surface-modified silver nanoparticles was measured with a dynamic light scattering method ZETA NANOSIZER SERIES NANO S (trade name; manufactured by Malvern Panalytical Ltd.) as an analysis apparatus, which was 28 nm.

Inks B to K were obtained through the same procedure as that of the ink A, except that components with amounts shown in Table 1 were mixed.

TABLE 1

| | | Ink A | Ink B | Ink C | Ink D | Ink E | Ink F | Ink G | Ink H | Ink I | Ink J | Ink K |
|---|---|---|---|---|---|---|---|---|---|---|---|---|
| Particles | Silver Nanoparticles A | 35.0 | 37.0 | 38.5 | 39.0 | 30.0 | 25.0 | 20.0 | | 35.0 | | |
| | Silver Nanoparticles B | | | | | | | | 35.0 | | | |
| | Silver Nanoparticles C | | | | | | | | | | 35.0 | |
| | Copper Nanoparticles A | | | | | | | | | | | 35.0 |
| Solvent | 3,3,5-Trimethylcyclohexanol | 30.00 | 30.00 | 30.00 | 30.00 | 30.00 | 30.00 | 30.00 | 30.00 | 30.00 | 30.00 | 30.00 |
| | Hexylene Glycol | 30.00 | 30.00 | 30.00 | 30.00 | 30.00 | 30.00 | 30.00 | 30.00 | 30.00 | 30.00 | 30.00 |
| Additive | Polymer | 5.00 | 3.00 | 1.50 | 1.00 | 10.00 | 15.00 | 20.00 | 5.00 | | 5.00 | 5.00 |
| | HDDA | | | | | | | | | 5.00 | | |
| | PERBUTYL O | | | | | | | | | 0.13 | | |

The details of additives in Table 1 are as follows.
Polymer: a polymer of iBuMA/MMA/MAA=50/30/20 wt % (iBuMA: isobutyl methacrylate, MMA: methyl methacrylate, MAA: methacrylic acid), acid value: 130 mgKOH/g, weight-average molecular weight: 12000
HDDA: 1,6-hexanediol diacrylate, manufactured by Daicel-Allnex Ltd., average molecular weight: 226, acryloyl equivalent: 113, glass transition temperature: 105° C., the content of 1,6-hexanediol diacrylate in the component: 100 mass %
PERBUTYL O: tert-butyl peroxy-2-ethylhexanoate, manufactured by NOF Corporation (PERBUTYL is a registered trade name)

Formation of First Metal Layer and Second Metal Layer

A substrate for forming metal layers including a first metal layer and a second metal layer used in Example 1 was obtained through the following procedure.

The ink A was applied to one surface of a substrate (polyester film, LUMIRROR (registered trade name) #100-U34, manufactured by Toray industries Inc.) using an ink jet method such that the application width was 1.2 m and the dry film thickness was 1.0 As a result, a first coating film was formed. A heating treatment was performed on the substrate on which the first coating film was formed under conditions shown in Table 2 below (first heating treatment). In the heating treatment, a convection oven (manufactured by ESPEC Corporation) was used. Next, the ink A was applied to another surface (surface opposite to the side where the first coating film was formed) of the substrate using an ink jet method such that the application width was 1.2 m and the dry film thickness was 1.0 As a result, a second coating film was formed. A heating treatment was performed on the substrate on which the first coating film on which the heating treatment was performed and the second coating film were formed under conditions shown in Table 2 (second heating treatment). In the heating treatment, a convection oven (manufactured by ESPEC Corporation) was used. Through the above-described procedure, the substrate for forming metal layers including the first metal layer and the second metal layer in this order was obtained.

Substrates for forming metal layers used in the other Examples and Comparative Examples were obtained through the above-described procedure, except that inks shown in Table 2 below were used and conditions of the first heating treatment and the second heating treatment were changed as shown in Table 2 below.

Preparation of Transfer Film

The following thermoplastic resin composition was applied to a temporary support (polyethylene terephthalate film, thickness: 16 μm, haze: 0.12%) using a slit nozzle such that the application width was 1.0 m and the dry layer thickness was 3.0 μm. The formed coating film of the thermoplastic resin composition was dried at 80° C. for 40 seconds to form a thermoplastic resin layer.

The following water-soluble resin layer composition was applied to the surface of the formed thermoplastic resin layer using a slit nozzle such that the application width was 1.0 m and the dry layer thickness was 1.2 μm. The formed coating film of the water-soluble resin layer composition was dried at 80° C. for 40 seconds to form a water-soluble resin layer.

The following photosensitive composition was applied to the surface of the formed water-soluble resin layer using a slit nozzle such that the application width was 1.0 m and the dry layer thickness was 5.0 μm. The formed coating film of the photosensitive composition was dried at 100° C. for 2 minutes to form a photosensitive composition layer. A protective film (polypropylene film, thickness: 12 μm) was bonded to the photosensitive composition layer to prepare a transfer film.

Thermoplastic Resin Composition
A propylene glycol monomethyl ether acetate solution of a copolymer including benzyl methacrylate, methacrylic acid, and acrylic acid (concentration of solid contents: 30.0 mass %, Mw: 30,000, acid value: 153 mgKOH/g): 42.85 parts
NK ESTER A-DCP (manufactured by Shin-Nakamura Chemical Co., Ltd.): 4.33 parts
8UX-015A (manufactured by Taisei Fine Chemical Co., Ltd.): 2.31 parts
ARONIX TO-2349 (manufactured by Toagosei Co., Ltd.): 0.77 parts
MEGAFACE F-552 (manufactured by DIC Corporation): 0.03 parts
Methyl ethyl ketone (manufactured by Sankyo Chemical Co., Ltd.): 39.80 parts by mass
Propylene glycol monomethyl ether acetate (manufactured by Showa Denko K.K.): 9.51 parts
Compound having the following structure (a photoacid generator, a compound synthesized using a method described in paragraph “0227” of JP2013-47765A): 0.32 parts

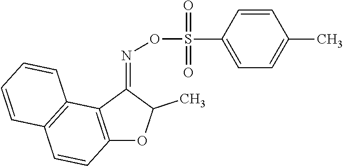 [SMILES: Cc1ccc(S(=O)(=O)O/N=C2/c3c(ccc4ccccc34)OC2C)cc1]

Compound having the following structure (colorant that is colored by an acid): 0.08 parts

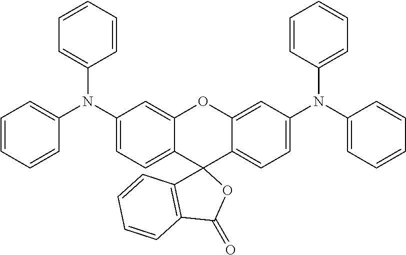 [SMILES: O=C1OC2(c3ccc(N(c4ccccc4)c4ccccc4)cc3Oc3cc(N(c4ccccc4)c4ccccc4)ccc32)c2ccccc21]

Water-Soluble Resin Composition
KURARAY POVAL PVA-205 (polyvinyl alcohol, manufactured by Kuraray Co., Ltd.): 3.22 parts by mass
Polyvinylpyrrolidone K-30 (manufactured by Nippon Shokubai Co., Ltd.): 1.49 parts by mass
MEGAFACE F-444 (fluorine-based surfactant, manufactured by DIC Corporation): 0.0015 parts by mass
Ion exchange water: 38.12 parts by mass
Methanol (manufactured by Mitsubishi Gas Chemical Company Inc.): 57.17 parts by mass

Photosensitive Composition
A propylene glycol monomethyl ether acetate solution of a copolymer of styrene/methacrylic acid/methyl methacrylate (concentration of solid contents: 30.0% by mass, a ratio between monomers: 52 mass %/29 mass %/19 mass %, Mw: 70,000): 23.4 parts by mass
BPE-500 (ethoxylated bisphenol A dimethacrylate, manufactured by Shin-Nakamura Chemical Co., Ltd.): 4.1 parts by mass
NK ester HD-N (1,6-hexanediol dimethacrylate, manufactured by Shin-Nakamura Chemical Co., Ltd.): 2.2 parts by mass
B-CIM (2,2′-bis(2-chlorophenyl)-4,4′,5,5′-tetraphenyl-1,2′-biimidazole, a photopolymerization initiator, manufactured by Kurogane Kasei Co., Ltd.): 0.25 parts by mass
SB-PI 701 (4,4′-bis(diethylamino)benzophenone, a sensitizer, available from Sanyo Trading Co., Ltd.): 0.04 parts by mass
TDP-G (phenothiazine, manufactured by Kawaguchi Chemical Industry Co., Ltd.): 0.0175 parts by mass
1-phenyl-3-pyrazolidone (manufactured by Fujifilm Wako Pure Chemical Corporation): 0.0011 parts by mass
Leuco crystal violet (manufactured by Tokyo Chemical Industry Co., Ltd.): 0.051 parts by mass
N-phenylcarbamoylmethyl-N-carboxymethyl aniline (manufactured by Fujifilm Wako Pure Chemical Corporation): 0.02 parts by mass
1,2,4-triazole (manufactured by Tokyo Chemical Industry Co., Ltd.): 0.75 parts by mass
MEGAFACE F-552 (fluorine-based surfactant, manufactured by DIC Corporation): 0.05 parts by mass
Methyl ethyl ketone (manufactured by Sankyo Chemical Co., Ltd.): 40.4 parts by mass
Propylene glycol monomethyl ether acetate (manufactured by Showa Denko K.K.): 26.7 parts by mass
Methanol (manufactured by Mitsubishi Gas Chemical Company Inc.): 2 parts by mass

Etching Treatment

After peeling off the protective film from the transfer film prepared through the above-described procedure, the photosensitive composition layer was bonded to both surfaces of the substrate for forming metal layers prepared through the above-described procedure under lamination conditions of roll temperature: 100° C., linear pressure: 0.8 MPa, and linear velocity: 3.0 m/min. Through the above-described procedure, the substrate for forming metal layers with the photosensitive composition layer was obtained. Next, in order to remove bubbles during the lamination, a heating defoaming treatment (0.6 MPa, 30 minutes) was performed.

A glass mask having a line-and-space pattern (Duty ratio 1:1) with a line width of 100 μm was closely attached to the temporary support without peeling off the temporary support, and the photosensitive composition layer on one side was exposed using an exposure machine (M-1S, manufactured by Mikasa Co., Ltd.). Next, the photosensitive composition layer on another side was exposed under the same conditions.

The laminate was left to stand for 1 hour after the exposure, the temporary support was peeled off, and a developer (30° C., a 0.66% potassium carbonate aqueous solution) was sprayed by showering. As a result, a non-exposed portion on the one side was removed, and a resist pattern was prepared. Likewise, a non-exposed portion on the other side was removed, and a resist pattern was prepared.

The exposure amount was adjusted to satisfy the condition where the line width of the resist pattern obtained by development through the line-and-space pattern (Duty ratio 1:1) mask with a line width of 100 μm was 100 μm.

The development time was determined using the following method. The above-described developer was sprayed to the non-exposed photosensitive composition layer by showering, a time required to remove the photosensitive composition layer was measured, and a time that was twice the required time was set as the development time.

An iron nitrate aqueous solution (30° C., 40.0 mass %) was sprayed to the obtained sample by showering, and the first metal layer and the second metal layer present in an opening portion of the resist pattern were removed by etching. Through the above-described procedure, a laminate including the first wiring pattern portion consisting of the first metal wires, the substrate, and the second wiring pattern portion consisting of the second metal wires in this order was obtained.

Further, a tetramethylammonium hydroxide (TMAH) aqueous solution (2.38 mass %) at 40° C. was sprayed by showering to remove the remaining resist pattern.

In each of Examples and Comparative Examples, the laminate was obtained through the above-described procedure using the substrate for forming metal layers obtained under conditions shown in Table 2 below.

Measurement and Evaluation

Regarding the laminate obtained in each of Examples and Comparative Examples, the measurement and the evaluation described below were performed. The measurement results and the evaluation results are shown in Table 2 below.

Additive Element Ratio

The content of each atom with respect to all the atoms of the first metal wires was obtained by preparing a sample where cross sections of the first metal wires were exposed and analyzing the cross sections of the first metal wires by X-ray photoelectron spectroscopy (XPS).

Specifically, the analysis by XPS was performed through the following procedure.

First, a first metal wire having a thickness of 1 μm and a width of 100 μm was obliquely cut using an ultramicrotome to expose a cross section of the first metal wire. In this case, the cut surface was adjusted such that the cross section of the first metal wire was more than the beam diameter of an irradiated X-ray used for XPS below.

In the XPS analysis of the cross section of the first metal wire, an X-ray photoelectron spectroscopic analyzer Quantera (manufactured by ULVAC-PHI, Inc.) was used. As the X-ray to be irradiated, a monochromatic Al Kα-ray (15 kV, 1 W) was used, and the beam diameter was 9 In addition, a photoelectron take-off angle was 45°, and a point analysis mode was used for the analysis. During the measurement, charge correction was performed using an electron gun and a low speed ion gun.

In order to remove the influence of surface contamination during cutting and storage, the cross section of the first metal wire was irradiated with argon ions to clean the outermost surface. Specifically, before the XPS analysis, the outermost surface of the cross section of the first metal wire was irradiated with argon ions under conditions of acceleration voltage: 2 kV, irradiation range: 2 square mm, and irradiation time: 30 seconds.

Based on the area intensities of peaks of C1s, N1s, O1s, Cl2p, Br3d, Ag3d, and Cu2p, the contents (at %) of carbon, nitrogen, oxygen, chlorine, and bromine with respect to all the atoms were calculated. In a case where an element other than the above-described elements was detected, the content of each of the elements was calculated in consideration of the area intensity of a peak corresponding to the element.

An analysis value of the first metal wire was shown in the following table. In a case where the analysis by XPS was performed on the second metal wire, the analysis value was the same as that of the first metal wire.

Resistivity Ratio

Using the above-described method, the resistivity R1 of the first metal wires and the resistivity R2 of the second metal wires were measured to calculate the resistivity ratio.

The resistivity ratio was evaluated based on the following standards.

Resistivity Ratio Evaluation Standards
A: the resistivity ratio was 1.00 or more and 1.10 or less.
B: the resistivity ratio was more than 1.10 and 1.20 or less.
C: the resistivity ratio was more than 1.20 and 1.40 or less.
D: the resistivity ratio was more than 1.40

Line Roughness Ratio

The average value A1 of the first metal wires and the average value A2 of the second metal wires were measured using the above-described method, and a ratio of a higher average value among the average value A1 and the average value A2 to a lower average value among the average value A1 and the average value A2 (hereinafter, also referred to as “line roughness ratio”) was calculated.

The line roughness ratio was evaluated based on the following standards.

Line Roughness Ratio Evaluation Standards
A: the line roughness ratio was 1.15 or more.
B: the line roughness ratio was 1.05 or more and less than 1.15.
C: the line roughness ratio was 1.00 or more and less than 1.05.

In a case where both of the line roughness ratio and the resistivity ratio were not 1.00, the resistivity R1 is more than the resistivity R2 in a case where the average value A1 is less than the average value A2, and the resistivity R2 is more than the resistivity R1 in a case where the average value A2 is less than the average value A1.

Photosensitive Composition Layer Adhesiveness

A cross-cut test of 100 squares was performed according to JIS standard (K5600-5-6: 1999). Specifically, the entire surface of the laminate with the photosensitive composition layer was exposed at the same exposure amount as the above-described mask exposure. After peeling off the temporary support, the laminate was cut using a cutter knife at intervals of 1 mm to form 100 lattices with 1 square mm. Next, a transparent adhesive tape #600 (manufactured by 3M) was pressure-bonded and was peeled off in the 180° direction. By observing the state of the lattices after the peeling, a remaining ratio (%) of lattices was obtained from the following expression based on the number of lattices peeled off from the photosensitive composition layer, and was set as an index for evaluating the adhesiveness.

Remaining Ratio (%)=(Number of All Lattices−Number of Lattices Peeled Off)/(Number of All Lattices)×100

Based on the calculated remaining ratio, the adhesiveness between the metal layer and the photosensitive composition layer was evaluated.

Adhesiveness Evaluation Standards
A: the remaining ratio was 95% or more.
B: the remaining ratio was 65% or more and less than 95%.
C: the remaining ratio was less than 65%.

Protective Film Peelability

The obtained laminate was interposed between two polyethylene films (thickness: 35 μm, manufactured by Tamapoly Co., Ltd.), and a load was applied from the upper and lower polyethylene films such that the surface pressure was 1 kgf/cm². Further, in a state where the load was applied, the laminate was left to stand in an environment of 30° C. for 3 days. Next, edges of the two polyethylene films were held by right and left hands to stretch the polyethylene films in a direction perpendicular to the laminate. As a result, the polyethylene films were peeled off. Depending on the status of the peeling, the protective film peelability was evaluated based on the following standards. In a case where the evaluation result is A or B, one protective film can be stably peeled off, which is preferable. In addition, in a case where the evaluation result is A, a high force is not required during peeling, which is preferable.

Evaluation Standards of Protective Film Peelability
A: peeling continuously occurred on any one of the first wiring pattern portion side and the second wiring pattern portion side, and the peeling sound was not generated.
B: peeling continuously occurred on any one of the first wiring pattern portion side and the second wiring pattern portion side, and the peeling sound was generated.
C: peeling did not continuously occur on any one of the first wiring pattern portion side and the second wiring pattern portion side, and peeling occurred on the first wiring pattern portion side or the second wiring pattern portion side.

Preparation of Touch Panel Sensor

A touch panel sensor having a length of 20 cm and a width of 15 cm was prepared using the laminate obtained in each of Examples and Comparative Examples with reference to paragraph “0111” of WO2018/115106A. As a lead wire part of the prepared touch panel sensor, the first wiring pattern portion and the second wiring pattern portion of the laminate were used.

Initial Evaluation

The prepared touch panel sensor was drive 50 times as a sensor to check whether or not malfunction occurred. Based on the number of times of malfunction, an initial evaluation was performed based on the following standards.

Evaluation Standards of Initial Evaluation
A: malfunction did not occur.
B: malfunction occurred once or twice.
C: malfunction occurred three to five times.
D: malfunction occurred six or more times.

Moisture-Heat Resistance Evaluation

After bonding a pressure-sensitive adhesive sheet to the prepared touch panel sensor, the touch panel sensor was left to stand in a hot humid environment of 65° C. and a relative humidity of 90% for 450 hours and was drive 50 times as a sensor to check whether or not malfunction occurred. Based on the number of times of malfunction after leaving in the hot humid environment and the number of times of malfunction in the initial evaluation, a moisture-heat resistance evaluation was performed based on the following standards.

Regarding Comparative Examples, the moisture-heat resistance evaluation was not performed.

Evaluation standards of Moisture-Heat Resistance Evaluation
A: as compared to the initial evaluation, the number of times of malfunction after the moisture-heat resistance evaluation did not change or was increased by once or three times.
B: as compared to the initial evaluation, the number of times of malfunction after the moisture-heat resistance evaluation was increased by four or nine times.
C: as compared to the initial evaluation, the number of times of malfunction after the moisture-heat resistance evaluation was increased by ten or more times.

Results

Table 2 shows the manufacturing conditions, the measurement results, and the evaluation results of the laminates according to Examples and Comparative Examples.

In the additive element column of Table 2, the expression “>0.5” represents that the content of the corresponding element was more than 0.5 at %, and the expression “<0.1” represents that the content of the corresponding element was less than 0.1 at %.

TABLE 2

| | Ink including | | | | | | | | | |
|---|---|---|---|---|---|---|---|---|---|---|
| | Metal Particles | | | First Heating | | Second Heating | | | | |
| | | | Calcin [symbol] ion | Treatment | | Treatment | | Additive | | |
| | Ink | Additive | Temperature | Temperature | Time | Temperature | Time | Elements (at %) | | |
| | Kind | Metal | (° C.) | (° C.) | (min) | (° C.) | (min) | Carbon | Nitrogen | Oxygen |
| Example 1 | Ink A | Silver | 140 | 100 | 30 | 120 | 30 | 10 | >0.5 | >0.5 |
| Example 2 | Ink A | Silver | 140 | 100 | 30 | 130 | 30 | 10 | >0.5 | >0.5 |
| Example 3 | Ink A | Silver | 140 | 100 | 30 | 140 | 30 | 10 | >0.5 | >0.5 |
| Example 4 | Ink A | Silver | 140 | 100 | 30 | 140 | 30 | 10 | >0.5 | >0.5 |
| Example 5 | Ink A | Silver | 140 | 100 | 30 | 160 | 30 | 10 | >0.5 | >0.5 |
| Example 6 | Ink A | Silver | 140 | 1 [symbol] 0 | 30 | 1 [symbol] 0 | 30 | 10 | >0.5 | >0.5 |
| Example 7 | Ink A | Silver | 140 | 140 | 30 | 160 | 30 | 10 | >0.5 | >0.5 |
| Example 8 | Ink A | Silver | 140 | 160 | 2 | 160 | 30 | 10 | >0.5 | >0.5 |
| Example 9 | Ink A | Silver | 140 | 160 | 10 | 160 | 30 | 10 | >0.5 | >0.5 |
| Example 10 | Ink B | Silver | 140 | 100 | 30 | 140 | 30 | 6 | >0.5 | >0.5 |
| Example 11 | Ink C | Silver | 140 | 100 | 30 | 140 | 30 | 3 | >0.5 | >0.5 |
| Example 12 | Ink D | Silver | 140 | 100 | 30 | 140 | 30 | 2 | >0.5 | >0.5 |
| Example 13 | Ink E | Silver | 140 | 100 | 30 | 140 | 30 | 20 | >0.5 | >0.5 |
| Example 14 | Ink F | Silver | 140 | 100 | 30 | 140 | 30 | 10 | >0.5 | >0.5 |
| Example 15 | Ink G | Silver | 140 | 100 | 30 | 140 | 30 | 40 | >0.5 | >0.5 |
| Example 16 | Ink H | Silver | 140 | 100 | 30 | 140 | 30 | 10 | 0. [symbol] | >0.5 |
| Example 17 | Ink I | Silver | 140 | 100 | 30 | 140 | 30 | 10 | >0.5 | 0.2 |
| Example 18 | Ink J | Silver | 150 | 100 | 30 | 140 | 30 | 10 | >0.5 | >0.5 |
| Example 19 | Ink K | Copper | 180 | 1 [symbol] 0 | 30 | 180 | 30 | 10 | >0.5 | >0.5 |
| Comparative | Ink A | Silver | 140 | 160 | 30 | 1 [symbol] 0 | 30 | 10 | >0.5 | >0.5 |
| Example 1 | | | | | | | | | | |

| | | | | | Photosensitive | | Sensor Driving Properties | |
|---|---|---|---|---|---|---|---|---|
| | Additive | | | Line | Composition | Protective | | Moisture-Heat |
| | Elements (at %) | | Resistivity | Roughness | Layer | Film | Initial | Resistance |
| | Chlorine | Bromine | Ratio | Ratio | Adhesiveness | Peelability | Evaluation | Evaluation |
| Example 1 | <0.1 | <0.1 | A | B | C | B | A | C |
| Example 2 | <0.1 | <0.1 | A | A | B | A | A | B |
| Example 3 | <0.1 | <0.1 | A | A | A | A | A | A |
| Example 4 | <0.1 | <0.1 | B | C | A | C | B | A |
| Example 5 | <0.1 | <0.1 | A | A | A | A | A | A |
| Example 6 | <0.1 | <0.1 | B | B | A | B | B | A |
| Example 7 | <0.1 | <0.1 | C | B | A | B | C | A |
| Example 8 | <0.1 | <0.1 | B | B | A | B | B | A |
| Example 9 | <0.1 | <0.1 | C | A | A | A | C | A |
| Example 10 | <0.1 | <0.1 | A | A | A | A | A | A |
| Example 11 | <0.1 | <0.1 | A | B | B | B | A | B |
| Example 12 | <0.1 | <0.1 | A | C | C | C | A | C |
| Example 13 | <0.1 | <0.1 | A | A | A | A | A | A |
| Example 14 | <0.1 | <0.1 | B | A | A | A | B | A |
| Example 15 | <0.1 | <0.1 | C | B | A | B | C | A |
| Example 16 | <0.1 | <0.1 | A | A | B | A | A | B |
| Example 17 | <0.1 | <0.1 | A | A | B | A | A | B |
| Example 18 | 0.2 | 0.1 | A | A | A | A | A | B |
| Example 19 | <0.1 | <0.1 | A | A | A | A | A | B |
| Comparative | <0.1 | <0.1 | D | C | A | C | D | — |
| Example 1 | | | | | | | | |

[symbol]

indicates data missing or illegible when filed

It was found from the results of Table 2 that, the resistivity R1 and the resistivity R2 are the same value or the ratio (resistivity ratio) of a higher resistivity among the resistivity R1 and the resistivity R2 to a lower resistivity among the resistivity R1 and the resistivity R2 is more than 1.00 and 1.40 or less, the malfunction of the touch panel sensor is not likely to occur. On the other hand, in Comparative Examples where the resistivity ratio was more than 1.40, the malfunction of the touch panel sensor was likely to occur.

It was found from a comparison between Examples 18 and 3 that, in a case where the first metal wires and the second metal wires do not substantially include halogen atoms, the moisture-heat resistance is excellent.

It was found from a comparison between Examples 4 and 12 and the other Examples that, in a case where the line roughness ratio is 1.05 or more (preferably 1.15 or more), the protective film peelability is excellent.

It was found from a comparison between Example 12 and Examples 11 and 3 that, in a case where the content of carbon atoms with respect to all the atoms in the first metal wires and the second metal wires is 3 at % or more (preferably 6 at % or more), the protective film peelability is excellent.

It was found from a comparison between Example 15 and Examples 14 and 3 that, in a case where the content of carbon atoms with respect to all the atoms in the first metal wires and the second metal wires is 30 at % or less (preferably 20 at % or less), the malfunction of the touch panel sensor is less likely to occur.

It was found from a comparison between Examples 16 and 3 that, in a case where the first metal layer (first metal wires) and the second metal layer (second metal wires) include nitrogen atoms and the content of nitrogen atoms with respect to all the atoms is more than 0.5 at %, the adhesiveness of the photosensitive composition layer is excellent.

It was found from a comparison between Examples 17 and 3 that, in a case where the first metal wires and the second metal wires include oxygen atoms and the content of oxygen atoms with respect to all the atoms is more than 0.5 at %, the adhesiveness of the photosensitive composition layer is excellent.

It was found from a comparison between Examples 7, 9, and 15 and the other Examples that, in a case where the resistivity ratio is 1.20 or less (preferably 1.10 or less), the malfunction of the touch panel sensor is less likely to occur.

It was found from a comparison between Examples 4 and 3 and a comparison between Example 7 and Examples 5 and 6 that, in a case where the heating temperature in the second heating treatment is higher than the heating temperature in the first heating treatment by 25 degrees or higher, the malfunction of the manufactured touch panel sensor is less likely to occur.

What is claimed is:

1. A laminate comprising:
a substrate;
a first wiring pattern portion that is disposed on one surface side of the substrate and consists of a plurality of first metal wires; and
a second wiring pattern portion that is disposed on another surface side of the substrate and consists of a plurality of second metal wires,
wherein both of the first metal wires and the second metal wires include metal and carbon atoms, and
in a case where an average resistivity of the first metal wires is represented by a resistivity R1 and an average resistivity of the second metal wires is represented by a resistivity R2, the resistivity R1 and the resistivity R2 are the same value, or
a ratio of a higher resistivity among the resistivity R1 and the resistivity R2 to a lower resistivity among the resistivity R1 and the resistivity R2 is more than 1.00 and 1.40 or less.

2. The laminate according to claim 1,
wherein the resistivity R1 and the resistivity R2 are the same value, or
a ratio of a higher resistivity among the resistivity R1 and the resistivity R2 to a lower resistivity among the resistivity R1 and the resistivity R2 is more than 1.00 and 1.20 or less.

3. The laminate according to claim 1,
wherein the resistivity R1 and the resistivity R2 are the same value, or
a ratio of a higher resistivity among the resistivity R1 and the resistivity R2 to a lower resistivity among the resistivity R1 and the resistivity R2 is more than 1.00 and 1.10 or less.

4. The laminate according to claim 1,
wherein the metal is silver or copper.

5. The laminate according to claim 1,
wherein the first metal wires and the second metal wires do not substantially include halogen atoms.

6. The laminate according to claim 1,
wherein in a case where an average value of arithmetic average roughness of the first metal wires is represented by an average value A1 and an average value of arithmetic average roughness of the second metal wires is represented by an average value A2, a ratio of a higher average value among the average value A1 and the average value A2 to a lower average value among the average value A1 and the average value A2 is 1.05 or more.

7. The laminate according to claim 1,
wherein a content of carbon atoms with respect to all atoms of the first metal wires is 2 at % or more, the content being obtained by analyzing cross sections of the first metal wires by X-ray photoelectron spectroscopy, and
a content of carbon atoms with respect to all atoms of the second metal wires is 2 at % or more, the content being obtained by analyzing cross sections of the second metal wires by X-ray photoelectron spectroscopy.

8. The laminate according to claim 1,
wherein a content of carbon atoms with respect to all atoms of the first metal wires is 40 at % or less, the content being obtained by analyzing cross sections of the first metal wires by X-ray photoelectron spectroscopy, and
a content of carbon atoms with respect to all atoms of the second metal wires is 40 at % or less, the content being obtained by analyzing cross sections of the second metal wires by X-ray photoelectron spectroscopy.

9. The laminate according to claim 1,
wherein the first metal wires and the second metal wires include nitrogen atoms.

10. The laminate according to claim 1,
wherein the first metal wires and the second metal wires include oxygen atoms.

11. The laminate according to claim 1,
wherein the substrate is transparent.

12. The laminate according to claim 1,
wherein the metal is silver or copper,
the first metal wires and the second metal wires do not substantially include halogen atoms,
in a case where an average value of arithmetic average roughness of the first metal wires is represented by an average value A1 and an average value of arithmetic average roughness of the second metal wires is represented by an average value A2, a ratio of a higher average value among the average value A1 and the average value A2 to a lower average value among the average value A1 and the average value A2 is 1.05 or more,
a content of carbon atoms with respect to all atoms of the first metal wires is 2 at % or more, the content being obtained by analyzing cross sections of the first metal wires by X-ray photoelectron spectroscopy,
a content of carbon atoms with respect to all atoms of the second metal wires is 2 at % or more, the content being obtained by analyzing cross sections of the second metal wires by X-ray photoelectron spectroscopy,
a content of carbon atoms with respect to all atoms of the first metal wires is 40 at % or less, the content being obtained by analyzing cross sections of the first metal wires by X-ray photoelectron spectroscopy,
a content of carbon atoms with respect to all atoms of the second metal wires is 40 at % or less, the content being obtained by analyzing cross sections of the second metal wires by X-ray photoelectron spectroscopy, and
the substrate is transparent.

13. The laminate according to claim 1,
wherein the first metal wires and the second metal wires include nitrogen atoms, and
the first metal wires and the second metal wires include oxygen atoms.

14. A touch panel sensor comprising:
the laminate according to claim 1.

15. A touch panel sensor comprising:
the laminate according to claim 12.

16. A touch panel sensor comprising:
the laminate according to claim 13.

17. An electronic apparatus comprising:
the touch panel sensor according to claim 14.
